(19) United States
(12) Patent Application Publication
(10) Pub. No.: US 2023/0378279 A1
(43) Pub. Date: Nov. 23, 2023

(54) SYSTEM AND METHOD FOR TWO-DIMENSIONAL ELECTRONIC DEVICES

(71) Applicants: Manichandra Morampudi, Cambridge, MA (US); Siddhardh Chandra Morampudi, Cambridge, MA (US)

(72) Inventors: Manichandra Morampudi, Cambridge, MA (US); Siddhardh Chandra Morampudi, Cambridge, MA (US)

(21) Appl. No.: 18/140,669

(22) Filed: Apr. 28, 2023

Related U.S. Application Data
(60) Provisional application No. 63/343,791, filed on May 19, 2022.

(51) Int. Cl. H01L 29/267; H01L 29/76; H01L 29/66

(52) U.S. Cl. CPC H01L 29/267; H01L 29/7606; H01L 29/66462; H01L 29/66037; H01L 29/1606

(57) ABSTRACT

An electronic device includes a two-dimensional electron system (2DES) having a two-dimensional electron gas (2DEG) area, and a plurality of contacts arranged around the 2DEG area. Charge particle transport is confined within the 2DEG area and the charge particle transport within the 2DEG area operates within ballistic or hydrodynamic transport regimes. Examples of the two-dimensional system include free-standing graphene, heterostructures of GaAs/2DEG/AlGaAs and hBN/graphene/hBN, among others. Embodiments of the two-dimensional electronic devices include amplifiers, electronic vortex switches, frequency mixers, rectifiers, multipliers, electrically-controlled micro-scale magnetic field generators, sensors, magnetic sensors, bolometers, and phase shifters, among others.

### CROSS REFERENCE TO RELATED CO-PENDING APPLICATIONS

This application claims the benefit of U.S. provisional application Ser. No. 63/343,791 filed on May 19, 2022 and entitled “SYSTEM AND METHOD FOR TWO-DIMENSIONAL ELECTRONIC DEVICES”, which is commonly assigned and the contents of which are expressly incorporated herein by reference.

### FIELD OF THE INVENTION

The present invention relates to a system and a method for two-dimensional electronic devices, and more particularly to two-dimensional electronic devices that operate in the ballistic and hydrodynamic transport regimes.

### BACKGROUND OF THE INVENTION

Conventional electron transport in conducting materials is viewed as individual particles flowing in the host solid material and diffusing as they get scattered by lattice vibrations, defects and impurities of the host solid material. The electron transport in this case is Ohmic/diffusive and is based on momentum relaxing scattering, as shown in FIG. 2A. In cases where the host material is made free of defects and impurities, i.e. pure, and the temperature is very low, the electrons travel across the host material unperturbed until they collide with the edges and walls of the host material, as shown in FIG. 2B. The electron transport in this case is ballistic and the current distribution is uniform because the electrons move at the same rate near the walls as they do at the center of the material, as shown in FIG. 2D. If the temperature of this pure material is then increased, the electrons begin to interact with each other and scatter off each other more frequently than they collide with and scatter off the walls of the host material, as shown in FIG. 2C. The electron transport in this case is hydrodynamic and causes the electrons to flow faster in the center of the host material and slower near the walls of the host material, similar to water flowing through a pipe, as shown in FIG. 2E.

In recent years, researchers have created extremely clean samples from 2D materials such as graphene to use for studying ballistic and hydrodynamic electron transport. The vast majority of this work, however, involved measuring electron transport properties. There is still a need for developing and designing new electronic devices based on ballistic and hydrodynamic electron transport.

### SUMMARY OF THE INVENTION

The present invention relates to a system and a method for two-dimensional electronic devices, and more particularly to two-dimensional electronic devices that operate in the ballistic and hydrodynamic transport regimes. Embodiments of the two-dimensional electronic devices include amplifiers, electronic vortex switches, frequency mixers, rectifiers, multipliers, electrically-controlled micro-scale and/or nano-scale magnetic field generators, sensors, magnetic sensors, bolometers, and phase shifters, among others. The devices may have a linear output or a non-linear output.

In general, in one aspect the invention provides an electronic device including a two-dimensional electron system (2DES) having a two-dimensional electron gas (2DEG) area, and a plurality of contacts arranged around the 2DEG area. Charge particle transport is confined within the 2DEG area and the charge particle transport within the 2DEG area operates within ballistic or hydrodynamic transport regimes.

Implementations of this aspect of the invention include the following. The charge particle transport within the 2DEG area has a momentum-relaxing mean free path lₘᵣ equal or larger than the 2DEG area's scale W:

lₘᵣ≳W.

The 2DEG comprises graphene. The 2DEG layer is arranged between two layers of semiconductor materials. The 2DEG layer is arranged between an AlGaAs layer and a GaAs layer. The 2DEG layer is arranged between a first layer of hBN layer and a second layer of hBN. The 2DES may be one of amplifiers, electronic vortex switches, frequency mixers, rectifiers, multipliers, electrically-controlled micro-scale magnetic field generators, sensors, magnetic sensors, bolometers, or phase shifters. The device may have a non-linear output. The charge particle transport may be one-dimensional, or two-dimensional.

In general, in another aspect the invention provides an amplifier device including a two-dimensional electron system (2DES) having a two-dimensional electron gas (2DEG) area arranged between a first semiconductor layer and a second semiconductor layer. A primary channel is formed within the 2DEG area and charge particle transport is confined within the primary channel. A plurality of contacts is arranged around the primary channel, and the contacts include an input/emitter contact, an output/collector contact and a ground/base contact. The charge particle transport within the primary channel operates within ballistic or hydrodynamic transport regimes. The charge particle transport within the primary channel has a momentum-relaxing mean free path (lₘᵣ) equal or larger than the primary channel's width W:

lₘᵣ≳W.

The primary channel is formed within the 2DEG by lithographic techniques comprising etching at a top layer, electrostatic gating, dry/wet etching, reactive ion etching, focused ion beam milling, electron beam lithography, and photo-lithography. The contacts comprise one of metal contacts or secondary channels formed within the primary channel. An input current signal injected into the input/emitter contact is amplified by an amount G=W/Wₑ at the output/collector contact, wherein W is the primary channel's width and Wₑ is the input/emitter contact's width.

In general, in another aspect the invention provides an electronic switch device including a two-dimensional electron system (2DES) having a two-dimensional electron gas (2DEG) area. An input channel is formed within the 2DEG area along a first direction and an output channel is formed within the 2DEG area along a second direction and has a first end connected perpendicularly to the input channel. Charge particle transport is confined within the input and output channels. An input contact is arranged at a first end of the input channel, a ground contact is arranged at a second end of the input channel opposite to the first end and an output contact is arranged at a second end opposite to the first end of the output channel. The charge particle transport within the input and output channels operates within ballistic or hydrodynamic transport regimes in a switch OFF state and within Ohmic/diffusive transport regime in a switch ON state. A first amount of current flows from the input contact to the output contact in the ON state and a second amount of current flows from the input contact to the output contact in the OFF state and wherein the second amount of current is smaller than the first amount of current.

In general, in another aspect the invention provides a device used to generate a magnetic field including a two-dimensional electron system (2DES) having a two-dimensional electron gas (2DEG) area. An input channel is formed within the 2DEG area along a first direction and an output channel is formed within the 2DEG area along a second direction and has a first end connected perpendicularly to the input channel and extending away from the input channel. Charge particle transport is confined within the input and output channels. An input contact is arranged at a first end of the input channel, and an output contact is arranged at a second end of the input channel opposite to the first end. A current vortex is formed within the output channel when the charge particle transport within the input channel operates within ballistic or hydrodynamic transport regimes and wherein the current vortex generates a magnetic field in a direction perpendicular to the 2DEG area and in a plane parallel to the 2DEG area. When the charge particle transport within the input channel operates within the hydrodynamic transport regime a single current vortex is formed within the output channel. When the charge particle transport within the input channel operates within the ballistic transport regime a plurality of current vortices is formed within the output channel. The current vortices configuration depends upon the 2DEG material's Fermi surface shape. For a 2DEG material with a circular Fermi surface the current vortices comprise a first dominant current vortex and several smaller current vortices. For a 2DEG material with a non-circular Fermi surface the current vortices comprise several current vortices of the same size and shape.

In general, in another aspect the invention provides an electronic device including a two-dimensional electron system (2DES) having a two-dimensional electron gas (2DEG) area. A first channel is formed within the 2DEG area along a first direction and a second channel is formed within the 2DEG area along a second direction and has a first end connected perpendicularly to the first channel. Charge particle transport is confined within the first and second channels. A first input contact is arranged at a first end of the first channel, a second input contact is arranged at a second end of the first channel opposite to the first end and a first output contact is arranged at a second end opposite to the first end of the second channel. A first current input and a second current input are injected into the first channel via the first input contact and the second input contact, respectively, and an output current exits the second channel through the first output contact. The charge particle transport within the first and second channels operates within ballistic or hydrodynamic transport regimes and the output current is a non-linear function of the first and second current inputs. The first and second input currents are DC currents and the device is used as a DC frequency multiplier. The first and second input currents are AC currents having a first and second frequencies, respectively, and the output current comprises a DC component and an AC component, and wherein when the first and second frequencies are the same the AC component has a frequency double the first or the second frequency and the device is used as a rectifier and an AC frequency multiplier. The first and second input currents are AC currents having a first and second frequencies, respectively, and the output current comprises a DC component and an AC component, and wherein when the first and second frequencies are not the same the AC component comprises frequencies equal to the sum of the first and second input currents' frequencies and the difference of the first and second input currents' frequencies and the device is used as a frequency mixer. The device may further include a voltage difference across the first output contact and a contact arranged at a bottom edge of the input channel opposite to the first output contact.

In general, in another aspect the invention provides an electronic phase shifter device including a two-dimensional electron system (2DES) having a two-dimensional electron gas (2DEG) area. An input channel is formed within the 2DEG area along a first direction, and a middle channel is formed within the 2DEG area along a second direction and has a first end connected perpendicularly to the input channel. A mixing channel is formed within the 2DEG area along the second direction having an end connecting to a second end of the middle channel, opposite the first end. Charge particle transport is confined within the input channel, the middle channel and the mixing channel. An input contact is arranged at a first side edge of the input channel, a first grounded contact is arranged at a first side edge of the middle channel, a second grounded contact is arranged at a first side edge of the output channel, and an output contact is arranged at a second side edge of the output channel. When the charge particle transport within the input, middle and output channels operates within ballistic or hydrodynamic transport regimes a current flow in the output channel is phase shifted relative to a current flow in the input channel. For a DC input current, the current flow in the output channel is perpendicular to the current flow in the input channel.

The details of one or more embodiments of the invention are set forth in the accompanying drawings and description below. Other features, objects and advantages of the invention will be apparent from the following description of the preferred embodiments, the drawings and from the claims.

### BRIEF DESCRIPTION OF THE DRAWINGS

Referring to the figures, wherein like numerals represent like parts throughout the several views:

FIG. 1A is a schematic diagram of a two-dimensional electron system (2DES) based on a heterostructure that includes a two-dimensional electron gas (2DEG) layer arranged between an AlGaAs layer, and a GaAs layer;

FIG. 1B is a schematic diagram of a two-dimensional electron systems (2DES) based on a heterostructure that includes a two-dimensional electron gas (2DEG) layer arranged between two hBN layers;

FIG. 1C is a schematic diagram of a two-dimensional electron systems (2DES) based on a free-standing graphene;

FIG. 2A is a schematic diagram of Ohmic/Diffusive electron transport in a 2-dimensional electron gas (2DEG);

FIG. 2B is a schematic diagram of Ballistic electron transport in a 2-dimensional electron gas (2DEG);

FIG. 2C is a schematic diagram of Hydrodynamic electron transport in a 2-dimensional electron gas (2DEG);

FIG. 2D depicts the electron velocity profile across a two-dimensional channel of width w for Ohmic and Ballistic electron transport;

FIG. 2E depicts the electron velocity profile across a two-dimensional channel of width w for hydrodynamic electron transport;

FIG. 3A is a schematic diagram of a current amplifier device based on non-Ohmic/non-diffusive charge transport according to this invention;

FIG. 3B is a schematic diagram of a first embodiment of the current amplifier device, according to this invention;

FIG. 3C is a schematic diagram of a second embodiment of the current amplifier device, according to this invention;

FIG. 3D is a schematic diagram of a third embodiment of the current amplifier device, according to this invention;

FIG. 4 is a schematic diagram of Ohmic/Diffusive electron transport in a current amplifier device with injection/emitter contact width Wₑ=0.1 μm, ground/base contact width W_{b}=0.9 μm and output/collector contact width W_{c}=1 μm;

FIG. 5 is a schematic diagram of ideal ballistic or hydrodynamic electron transport in a current amplifier device with injection/emitter contact width Wₑ=0.1 μm, ground/base contact width W_{b}=0.9 μm and output/collector contact width W_{c}=1 μm;

FIG. 6 is a schematic diagram of ballistic or hydrodynamic electron transport with finite momentum-relaxing scattering in a current amplifier device with injection/emitter contact width Wₑ=0.1 μm, ground/base contact width W_{b}=0.9 μm and output/collector contact width W_{c}=1 μm;

FIG. 7 is a gain versus frequency graph of a current amplifier device with an emitter contact width Wₑ=0.1 μm, base contact width W_{b}=0.9 μm and collector contact width Wₑ=1 μm in the ballistic and hydrodynamic regimes;

FIG. 8 is a DC gain versus the momentum relaxing scattering time T., graph of a current amplifier device with an emitter contact width Wₑ=0.1 μm, base contact width W_{b}=0.9 μm and collector contact width Wₑ=1 μm in the ballistic and hydrodynamic regimes;

FIG. 9A depicts the current noise of an amplifier device with injection/emitter contact width Wₑ=0.1 μm, ground/base contact width W_{b}=0.9 μm and output/collector contact width W_{c}=1 μm (magnified by 100×) as a function of frequency, with the output signal shown in dotted line;

FIG. 9B depicts the output current of the amplifier device according to this invention as a function of frequency;

FIG. 9C depicts the signal to noise ratio of the amplifier device according to this invention as a function of frequency;

FIG. 10 is a schematic diagram of an electronic switch according to this invention that can toggle between ON and OFF states;

FIG. 11 is a schematic diagram of Ohmic/Diffusive electron transport in the electronic switch device of FIG. 10;

FIG. 12 is a schematic diagram of ballistic electron transport in the electronic switch device of FIG. 10;

FIG. 13 is a schematic diagram of hydrodynamic electron transport in the electronic switch device of FIG. 10;

FIG. 14 depicts the gain graph as a function of the momentum relaxing scattering time in the electronic switch device of FIG. 10;

FIG. 15 depicts the gain graph as a function of time in the electronic switch device of FIG. 10;

FIG. 16 is a schematic diagram of a device used to generate magnetic fields over very small spatial scales according to this invention;

FIG. 17 is a schematic diagram of Ohmic/Diffusive electron transport in the device of FIG. 16;

FIG. 18 is a schematic diagram of ballistic electron transport in the device of FIG. 16;

FIG. 19 is a schematic diagram of hydrodynamic electron transport in the device of FIG. 16;

FIG. 20A depicts spatial profiles of the density and currents in the device of FIG. 16 having dimensions Wᵢₙ=0.25 μm, Lᵢₙ=1 μm Wₒᵤₜ=1 μm and Lₒᵤₜ=5.25 μm and having a circular Fermi surface;

FIG. 20B depicts spatial profiles of the density and currents in the device of FIG. 16 having dimensions Wᵢₙ=0.25 μm, Lᵢₙ=1 μm Wₒᵤₜ=1 μm and Lₒᵤₜ=1 μm and having a hexagonal Fermi surface and where the outgoing current exits the Fermi surface at an angle θ=π/6 relative to the injected current in two different directions;

FIG. 20C depicts spatial profiles of the density and currents in the device of FIG. 16 having dimensions Wᵢₙ=0.25 μm, Lᵢₙ=1 μm, Wₒᵤₜ=1 μm and Lₒᵤₜ=1 μm and having a hexagonal Fermi surface and where the outgoing current exits the Fermi surface at an angle θ=π/3 relative to the injected current in three different directions;

FIG. 21A depicts spatial profiles of the density and currents in the device of FIG. 16 having aspect ratio of Lₒᵤₜ/Lᵢₙ=1(left) and Lₒᵤₜ/Lᵢₙ=5(right) for Ohmic/Diffusive electron transport and having a hexagonal Fermi surface and where the outgoing current exits the Fermi surface at an angle θ=π/6 relative to the injected current in two different directions;

FIG. 21B depicts spatial profiles of the density and currents in the device of FIG. 16 having aspect ratio of Lₒᵤₜ/Lin1(left) and Lₒᵤₜ/Lᵢₙ=5(right) for hydrodynamic electron transport and having a hexagonal Fermi surface and where the outgoing current exits the Fermi surface at an angle θ=π/3 relative to the injected current in three different directions;

FIG. 21C depicts spatial profiles of the density and currents in the device of FIG. 16 having aspect ratio of Lₒᵤₜ/Lᵢₙ=1(left) and Lₒᵤₜ/Lᵢₙ=5(right) for ballistic electron transport and having a hexagonal Fermi surface and where the outgoing current exits the Fermi surface at an angle θ=π/6 relative to the injected current in two different directions;

FIG. 21D depicts spatial profiles of the density and currents in the device of FIG. 16 having aspect ratio of Lₒᵤₜ/Lᵢₙ=1(left) and Lₒᵤₜ/Lᵢₙ=5(right) for ballistic electron transport and having a hexagonal Fermi surface and where the outgoing current exits the Fermi surface at an angle θ=π/3 relative to the injected current in three different directions;

FIG. 22 depicts spatial profiles of the density and currents in the device of FIG. 16 having dimensions Wᵢₙ=0.25 μm, Lᵢₙ=1 μm, Wₒᵤₜ=1 μm and Lₒᵤₜ=5 μm and having a circular Fermi surface (a) and magnetic fields of the device at 250 nm above the plane of the 2DEG (b)-(d);

FIG. 23 depicts spatial profiles of the density and currents in the device of FIG. 16 having dimensions Wᵢₙ=0.25 μm, Lᵢₙ=1 μm, Wₒᵤₜ=1 μm and Lₒᵤₜ=5 μm and having a hexagonal Fermi surface (a) and where the outgoing current exits the Fermi surface at an angle θ=π/3 relative to the injected current in three different directions and profiles of the magnetic fields of the device at 250 nm above the plane of the 2DEG (b)-(d);

FIG. 24 depicts spatial profiles of the density and currents in the device of FIG. 16 having dimensions Wᵢₙ=0.25 μm, Lᵢₙ=1 μm, Wₒᵤₜ=1 μm and Lₒᵤₜ=5 μm and having a hexagonal Fermi surface (a) and where the outgoing current exits the Fermi surface at an angle θ=π/6 relative to the injected current in two different directions and profiles of magnetic fields of the device at 250 nm above the plane of the 2DEG (b)-(d);

FIG. 25 is a schematic diagram of a device used as a frequency mixer, rectifier and multiplier, in the current mode, according to this invention;

FIG. 26 is a schematic diagram of a device used as a frequency mixer, rectifier and multiplier, in the voltage mode, according to this invention;

FIG. 27 depicts spatial profiles of the voltages of the device of FIG. 25 in the ohmic/diffusive, ballistic and hydrodynamic regimes;

FIG. 28 depicts spatial profiles of the currents of the device of FIG. 26 in the ohmic/diffusive, ballistic and hydrodynamic regimes;

FIG. 29 depicts a graph of the output current versus the input DC current for the device of FIG. 25 in the ballistic regime;

FIG. 30 depicts a graph of the output voltage difference versus the input DC current for the device of FIG. 26 in the ohmic/diffusive, ballistic and hydrodynamic regimes;

FIG. 31 depicts a graph of the input and output AC currents versus time for the device of FIG. 25 in the ballistic regime and hydrodynamic regimes;

FIG. 32 depicts a power spectrum of the input and output currents versus frequency for the device of FIG. 25 in the ballistic regime and hydrodynamic regimes;

FIG. 33 is a schematic diagram of an electronic phase shifter device, according to this invention;

FIG. 34 depicts spatial profiles of the currents of the device of FIG. 33 in the ohmic/diffusive, ballistic and hydrodynamic regimes;

FIG. 35 depicts a graph of the input and output AC currents versus time for the device of FIG. 33;

FIG. 36 depicts a graph of the phase shift versus the device size (graph b) and a graph of the gain versus the device size (graph c) for the device of FIGS. 33; and

FIG. 37 depicts a graph of the phase shift versus frequency and a graph of the gain versus frequency for the device of FIG. 33.

### DETAILED DESCRIPTION OF THE INVENTION

The present invention relates to a system and a method for two-dimensional electronic devices, and more particularly to two-dimensional electronic devices that operate in the ballistic and hydrodynamic transport regimes. Embodiments of the two-dimensional electronic devices include amplifiers, electronic vortex switches, frequency mixers, rectifiers, multipliers, electrically-controlled micro-scale magnetic field generators, sensors, magnetic sensors, bolometers, and phase shifters, among others. The devices may have a linear output or a non-linear output.

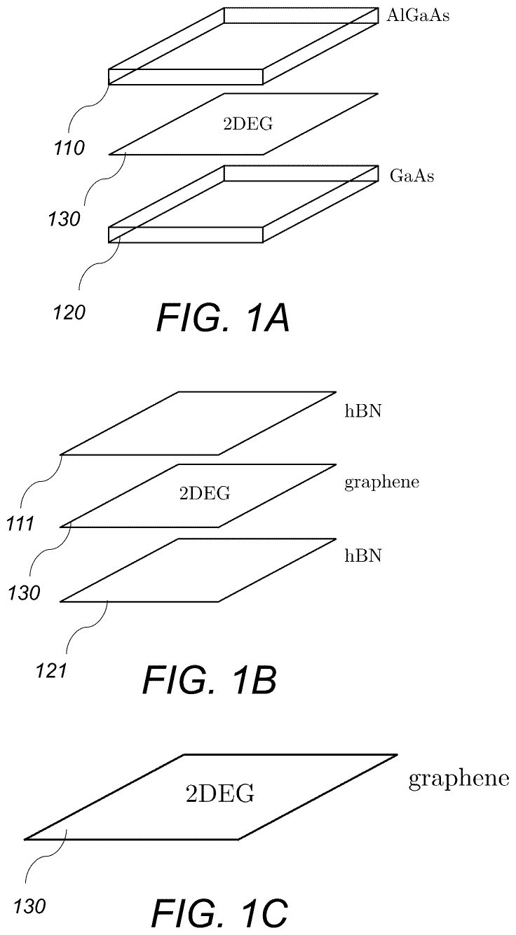

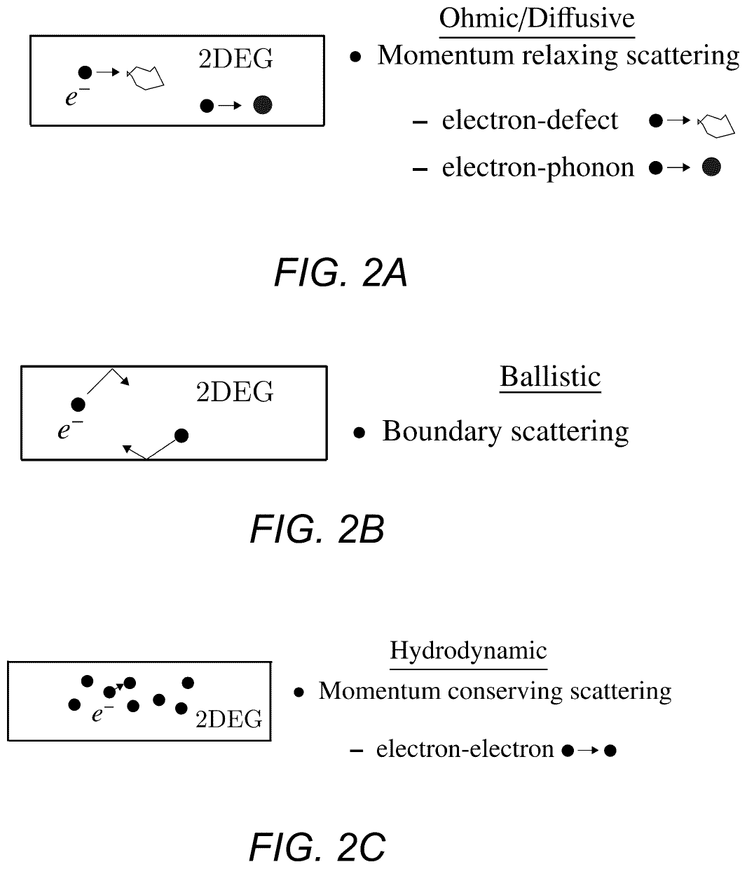

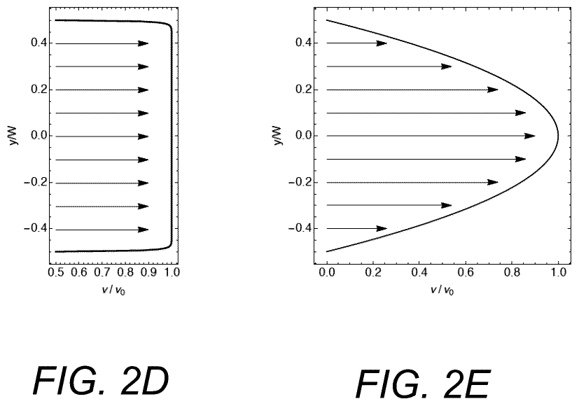

Hydrodynamic and ballistic electron flows are non-diffusive electronic transport regimes that set in when momentum-dissipation (due to electron-defect, electron-phonon scattering) becomes sufficiently small, as shown in FIG. 2C and FIG. 2B, respectively. Such a scenario is now routine in several two-dimensional electron systems (2DES), such as a free-standing graphene (shown in FIG. 1C), or heterostructures of GaAs/2DEG/AlGaAs (shown in FIG. 1A), or hBN/graphene/hBN (shown in FIG. 1B), wherein the momentum-dissipating mean free path is several microns across a large temperature range. Ballistic charge transport occurs at low temperatures, where electron-electron scattering is weak, and so electrons scatter predominantly against the device boundaries, as shown in FIG. 2B. The hydrodynamic regime sets in at relatively higher temperatures, when electron-electron scattering becomes dominant, as shown in FIG. 2C. The resulting electron transport resembles that of a classical two-dimensional fluid. These ballistic and hydrodynamic (BH) regimes are inherently more efficient, owing to low momentum-dissipation. Crucially, they are also capable of generating completely new device characteristics in two-dimensional geometries and are not just more efficient versions of diffusive electronics, as in the one-dimensional case of High Electron Mobility Transistors (HEMTs) which can directly be compared with silicon MOSFETs.

Despite occurring at opposite limits of the strength of electron-electron scattering, ballistic and hydrodynamic regimes are remarkably similar. They both display striking collective features, such as current vortices, and have closely related nonlocal current-voltage relations that give rise to device characteristics not possible with diffusive transport, where the current-voltage relation is local, as shown in FIG. 2A. The current-voltage relations in BH regimes, because of their nonlocality, are set entirely by the device geometry. Therefore, a chosen set of device characteristics can be engineered by creating an appropriate pattern in the 2DES system. This opens up the possibility of creating practical devices (e.g., diodes, amplifiers, switches) which are not only superior in performance but also feature a much simpler lithographic process compared to present day electronics. The design methodology required for BH electronics is very different compared to the latter, wherein discrete diffusive elements with well-defined characteristics are assembled together to make a composite circuit with the desired behaviour. On the other hand, the design of BH devices requires a continuum approach: the collective flow of electrons needs to be guided in a suitable manner so as to achieve the desired characteristics.

Transport in the BH device is modeled via the Boltzmann equation (1),

$$\frac{\partial f}{\partial t} + v \cdot \frac{\partial f}{\partial x} = - \frac{f - {f}_{0}^{mr}}{{τ}_{mr}} - \frac{f - {f}_{0}^{mc}}{{τ}_{m c}} \qquad ( 1 )$$

where f(x, p,t) is the electron distribution in the spatial coordinates x=(x, y), momentum coordinates p=(px, py), and time t. The equation describes the semiclassical evolution of charge carriers with the band velocity v=∂E/∂p, where E(p) is the band energy dispersion. While long-range electric fields are not explicitly present in equation (1), they are included at linear order as the gradient of the electrochemical potential. The left side describes free advection, and the right side thermalization due to momentum-relaxing (MR) and momentum-conserving (MC) scattering in a relaxation time approximation with f₀^{mr} and f₀^{mc} the local stationary and drifting Fermi-Dirac distributions. The model inputs are the scattering time scales τ_{mc} (set by normal electron-electron scattering) and τₘᵣ (set by electron-defect, electron-phonon and Umklapp electron-electron scattering). We solve equation (1) in the precise experimental geometry using a Boltzmann solver. In one example, the Boltzmann solver is BOLT, an open source high-resolution solver for kinetic theories. The usual Ohmic transport arises in the limit τₘᵣ« L/ν_{F}, where L is the device scale and ν_{F} is the Fermi velocity. When τₘᵣ≥L/ν_{F} is satisfied, Ohmic transport breaks down, and either ballistic or hydrodynamic transport sets in depending on whether τₘᵣ≥L/ν_{F} (ballistic flow) or τₘᵣ«L/ν_{F} (hydrodynamic flow). Material specific properties enter through the band energy E(p), and the scattering time scales τₘᵣ and τ_{mc}. The transport characteristics also hold beyond the semi-classical regime, such as the phase coherent regime, which is modeled with software designed to handle such regimes.

We showcase a novel form of current amplification enabled by BH flows, wherein all transport is planar, i.e., confined to within the ultra-high mobility 2DES system. In contrast, the traditional FET amplifier architecture involves feeding the input signal at the backgate, which modulates the output channel conductivity.

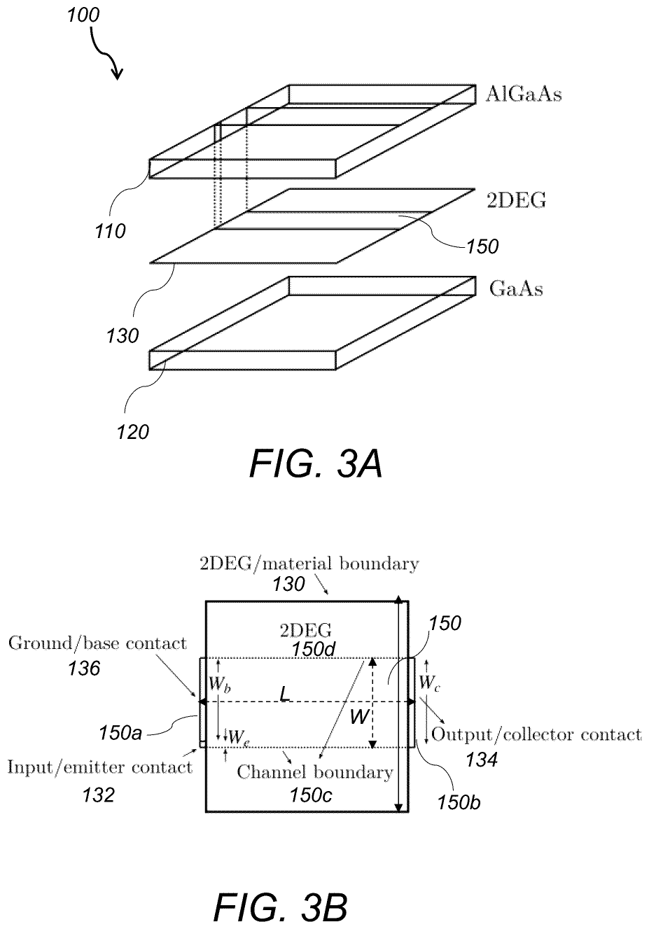

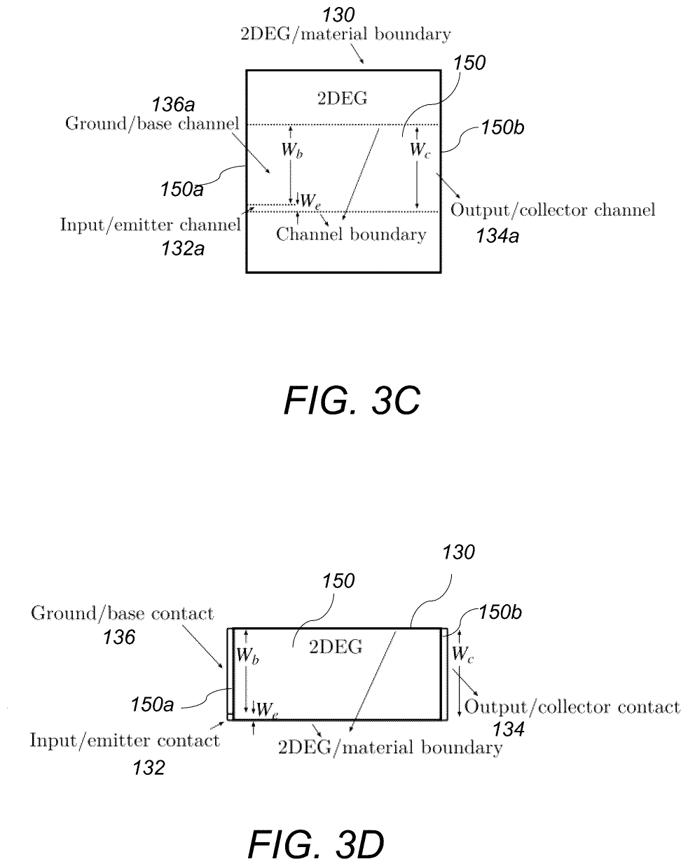

Referring to FIG. 3A-FIG. 3D, a current amplifier device 100 based on non-Ohmic/non-diffusive charge transport according to this invention includes a two-dimensional electron gas (2DEG) layer 130 arranged between an AlGaAs layer 110, and a GaAs layer 120. In one example, the 2DEG layer 130 is graphene. The two-dimensional electron gas has a momentum-relaxing mean free path that is sufficiently large so as to lead to a breakdown of Ohmic/diffusive transport. The three-terminal current amplifier device 100 includes a small input/emitter contact 132 (emitter) at the bottom-left of the 2DEG structure, a large output/collector contact 134 (collector) on the right side of the 2DEG structure, and another large ground/base contact 136 (base) on the left side of the 2DEG structure. A channel 150 is formed within the 2DEG that constitutes the main body of the amplifier, in which charge carriers are confined to move in. The charge particle transport within channel 150 is one-dimensional or two-dimensional. A signal to be amplified is fed into the input contact 132 and is read out through the output contact 134. In one example, the 2DEG layer 130 is a rectangular that includes a channel 150 having a width W of about 10 μm and a length L of about 10 μm. The width of the emitter contact Wₑ is 1 μm, the width of the base contact W_{b} is 9 μm the width of the collector W_{c} is 10 μm. Device 100 is used to amplify an input signal with very low noise addition, power consumption and heat dissipation, and is capable of operating at extremely low temperatures and high frequencies.

As was mentioned above, charge carriers are confined to move within channel 150. The emitter contact 132 and the base contact 136 share one edge 150a of the channel 150, and the output contact 134 is placed on the opposite edge 150b of the channel 150. An incoming emitter current Iᵢₙ is fed in the device 100 and output current Iₒᵤₜ is extracted at the collector 134. In this embodiment, the top and bottom channel edges/boundaries 150c, 150d are within the top and bottom boundaries of the 2DEG material 130, while the left and right channel boundaries 150a, 150b extend beyond the left and right boundaries of the 2DEG material 130, as shown in FIG. 3A. In other embodiments, the left and right channel boundaries 150a, 150b extend to the left and right edges/boundaries of the 2DEG material 130, while the top and bottom channel boundaries 150c, 150d are within the top and bottom boundaries of the 2DEG material 130, as shown in FIG. 3C. In yet other embodiments, the left and right channel boundaries 150a, 150b are within the left and right edges/boundaries of the 2DEG material 130, while the top and bottom channel boundaries 150c, 150d extend to the top and bottom boundaries of the 2DEG material 130, as shown in FIG. 3D.

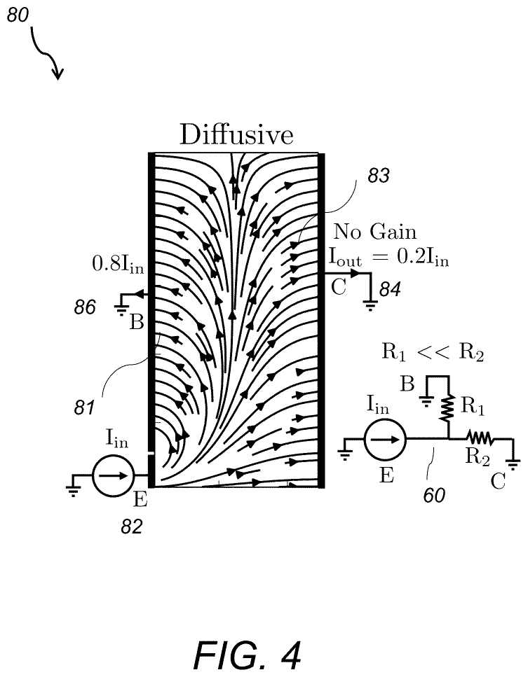

The channel 150 can be created using a variety of lithographic techniques, such as etching at the top layer, electrostatic gating, dry/wet etching, reactive ion etching, focused ion beam milling, electron beam lithography and photo-lithography, among others. The main channel 150 that defines the body of the amplifier may occupy the entirety of the 2DEG structure 130, i.e, the entire span of the material as shown in FIG. 3D. In this case, the boundaries of the channel 150 are then the boundaries of the material 130. In other cases the main channel 150 is formed within the 2DEG structure 130, as shown in FIG. 3B and FIG. 3C. The amplifier is formed by either using metallic contacts 132, 134, 136 with the appropriate geometry, where the boundary of the 2DEG is used to define the channel 150 (as shown in FIG. 3D), or by forming channels 132a, 134a, 136a lithographically within the 2DEG layer with the input signal sourced from a circuit to the left 82 (created in the 2DEG) and fed to another circuit 60 on right (also created in the 2DEG) (as shown in FIG. 4), or a combination of channels and contacts to create a standalone device.

For transport in the channel 150 to be non-diffusive/non-Ohmic, the momentum relaxing mean free path 1ₘᵣ should satisfy W , i.e., 1ₘᵣ>10 μm. This condition is satisfied over a wide range of temperatures in several materials including graphene, graphene/hBN, GaAs/AlGaAs heterostructures, and quasi-2D materials such as delafossites. The temperature range over which the condition is valid is material dependent. In GaAs/AlGaAs, the condition can be satisfied up to 77 K degrees, whereas in graphene and associated heterostructures, it can be satisfied even up to room temperatures.

There are two types of non-diffusive/non-Ohmic transport regimes: ballistic and hydrodynamic transport, both of which can be realized with sufficiently weak momentum relaxation (which occurs due to disorder, defect, phonon and Umklapp scattering), as made precise by the condition above. In the ballistic regime, charge carriers scatter predominantly against the channel boundaries, as shown in FIG. 2B. In the hydrodynamic regime, charge carriers scatter predominantly against each other, as shown in FIG. 2C.

Ballistic regime occurs at low currents and low temperatures, whereas the hydrodynamic regime occurs at relatively higher currents and higher temperatures. In GaAs/AlGaAs, the ballistic regime has been shown to occur for currents satisfying I≲100 nA and temperatures satisfying T≲20 K. At higher currents (100 nA≲I≲100 μA) and temperatures (20 K≲T≲77 K), electron-electron scattering is enhanced, leading to the onset of the hydrodynamic regime. Beyond a certain current and/or temperature, the excitation of a sufficient number of phonons causes the momentum-relaxing mean free path to fall below the device scale, thus causing the onset of the Ohmic regime. Typical currents and temperatures at which the Ohmic regime sets in are 100 μA and 77 K, respectively.

Ballistic transport can either be quantum phase-coherent or incoherent, i.e., semiclassical. In the former, the dynamics in the system is wave-like and can display characteristic wave phenomenon such as interference effects. In the latter, the dynamics in the system is particle-like. Phase-coherent ballistic transport occurs at mK temperatures and transitions into semi-classical ballistic transport at ˜1 K. The amplifier of this invention is able to operate in both phase-coherent and semi-classical ballistic transport.

As was mentioned above, the input 132 (also called emitter) and ground 136(also called base) contacts are placed on the left edge 150a of the channel, with no specific requirement in their vertical placements, i.e., the input contact can be either below or above the ground contact. The width of the input and ground contacts are Wₑ and W_{b} respectively. The sum of the widths is equal to the total vertical height of the channel W, i.e., Wₑ+W_{b}=W.

Further, the width of the ground contact W_{b} must be much larger than that of the input contact Wₑ, i.e., W_{b}» Wₑ. For W=10 μm, typical contact widths are Wₑ=1 μm and W_{b} =9 μm. On the right side 150b of the channel is the output contact 134 (also called collector). The width of the collector contact (W_{c}) is the same as the channel width (W), i.e, Wₑ=W=10 μm. From the constraints on the input and ground contacts widths above, we have W_{c}=W_{b}+Wₑ.

The input, ground, and output contacts can alternatively be channels 132a, 136a, 134a defined in the 2DEG, created using the same techniques as the main channel, as shown in FIG. 3C. One end of the input, ground and output channels are attached to the main channel 150 that defines the amplifier body, and the other end may be connected to metal contacts.

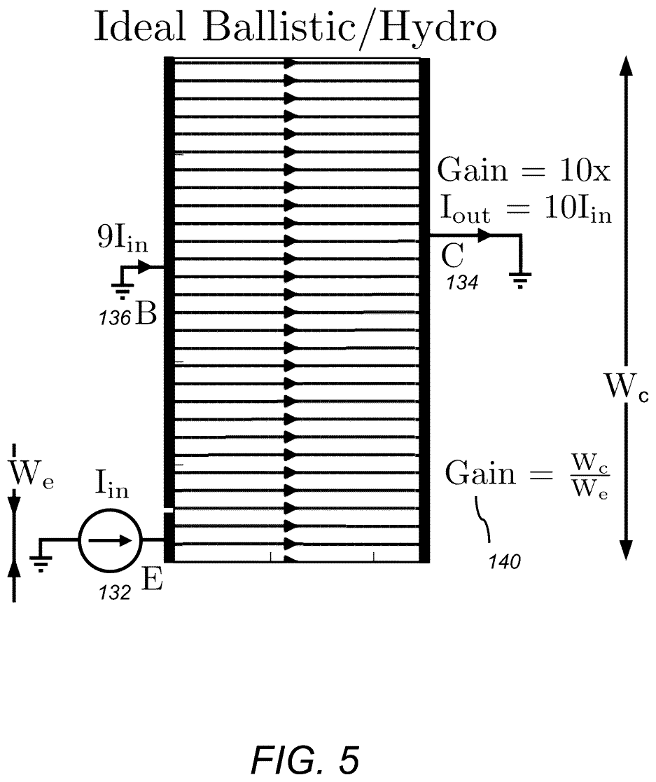

With the structure as described above, an input current signal Iᵢₙ injected into the channel 150 through the input contact 132 is amplified by an amount G=W/Wₑ at the output contact 134, where the current is Iₒᵤₜ=G x Iᵢₙ. For Wₑ=1 μm, W_{b}=9 μm and Wₑ=10 μm, the gain is G=10, as shown in FIG. 5.

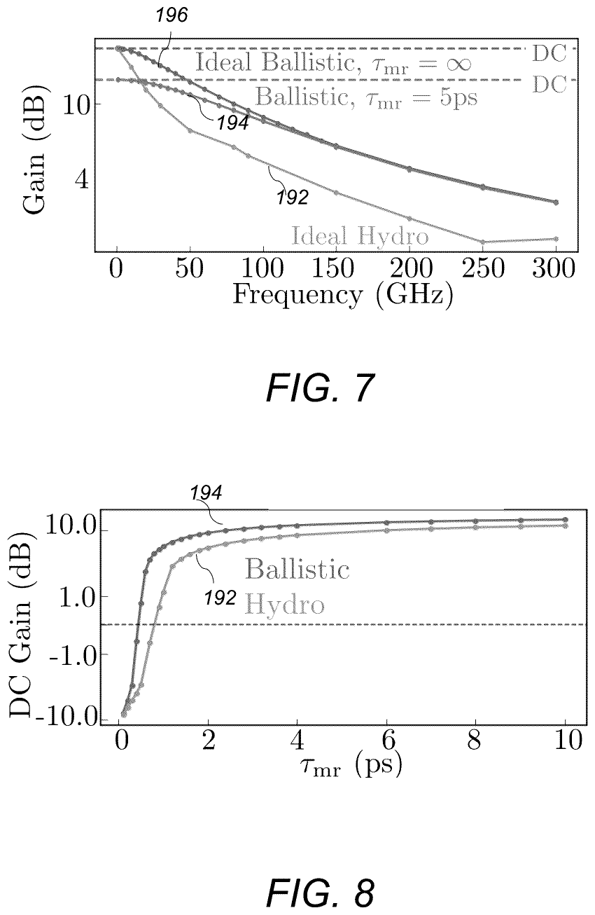

The amplification occurs in non-diffusive/non-Ohmic regimes, i.e., in both the ballistic 194, 196, and hydrodynamic 192 regimes, as shown in FIG. 7 and FIG. 8. However, beyond a certain threshold current and/or temperature, the momentum-relaxation mean free path becomes smaller than the device scale, i.e, 1ₘᵣ; W=10 μm, and the device transitions into an Ohmic regime, where no amplification is possible. The flow of current is diffusive, resembling a circuit with two parallel resistors, where the current takes all possible paths to ground, as shown in FIG. 4. The amplification can occur over a large frequency range (DC to 200 GHz) as shown in FIG. 7.

In another embodiment, device 100 is implemented in a structure that includes a two-dimensional electron gas (2DEG) layer 130 arranged between an hBN layer 111, and a hBN layer 121, as shown in FIG. 1B. In yet another embodiment, device 100 is implemented in a free-standing 2DEG layer 130, or quasi-2D materials, i.e., 3D materials in which transport is effectively 2D such as delafossites, as shown in FIG. 1C. In one example, the rectangular channel 150 in the 2DEG 130 has dimensions L×W , where L and W are ˜10 μm.

Referring to FIG. 4, in an amplifier device 80 where diffusive flow occurs, the injected current at the emitter 82 is dispersed into both the base 86 and the collector 84, as is typical of a circuit 60 with two resistors R1, R2, in parallel. The current 81 flowing into the base 86 is much larger than the current 83 flowing into the collector 84, because of its close proximity to the emitter 82, thus providing a path of lower resistance than the collector. In the example shown in FIG. 4, base current 81 is 0.8 Iᵢₙ, where Iᵢₙ is the incoming emitter current Iᵢₙ and the collector current 83 is 0.2 Iᵢₙ.

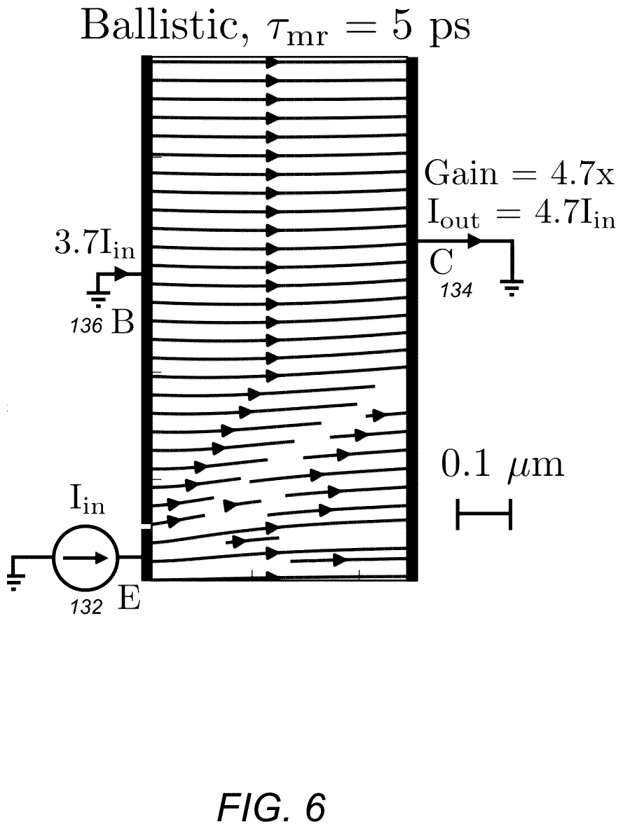

Referring to FIG. 5 and FIG. 6, the flow in the BH regimes is strikingly different form the diffusive flow of FIG. 4. In an amplifier device 100 where BH flow occurs, the current in the base 136 is constrained to flow in the same direction as that of the emitter 132. In the hydrodynamic regime, this flow pattern can be understood as arising due to viscous drag wherein the input current Iᵢₙ drags current from the grounded base 136 into the device. A crucial feature is that the amplifications occurs due to the nonlocality of the current-voltage relation, without needing any nonlinearity, thereby allowing the device to operate in linear transport and minimizing distortion. Remarkably, the flow in the ballistic regime, where hydrodynamic equations are not applicable, is also the same. Evidently, the ballistic and hydrodynamic regimes are degenerate to a large extent, which we exploit here to produce useful device characteristics that persist across a range of temperatures.

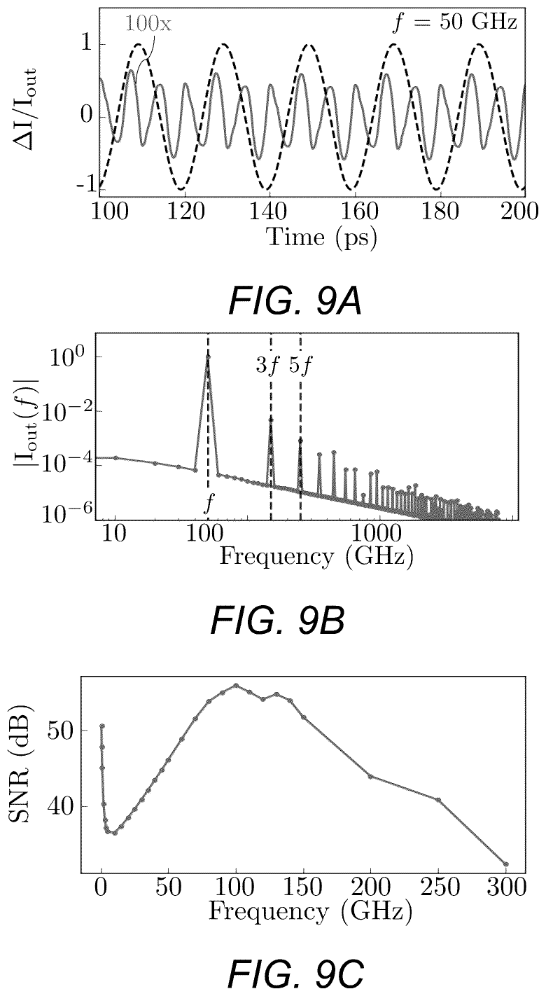

The current gain 140 is set entirely by the device geometry and is based on the ratio of the contact width of the collector (output) Wₑ 134 to that of the emitter (input) Wₑ 132. In the prototype device 100, shown in FIG. 5, the current gain 140 when operating in the ideal ballistic or hydrodynamic limit is 10 dB in DC. Because signal propagation in the device is planar, it is unaffected by parasitic capacitances typical of FETs, and thus features a very high cutoff frequency 300 GHz), as shown in FIG. 7. The gain persists even in the presence of finite (but sufficiently large) momentum-relaxation (MR) τₘᵣ=5 ps, and is especially robust at mmWave/terahertz frequencies 192, 194, becoming insensitive to the presence of MR scattering. The noise characteristics of the current simplifier 100 is shown in FIG. 9A-FIG. 9C. An intrinsic noise appears at the output, in the form of higher odd harmonics of the input AC signal, as shown in FIG. 9A. This noise appears despite the absence of any stochastic term in the Boltzmann equation, and is extremely small, resulting in a signal to noise ratio (SNR) of 40 dB over a large frequency range, as shown in FIG. 9C. The source of this noise is considered to be a fundamentally new collective quantum phenomenon exclusive to fermions -an excitation of angular modes on the Fermi surface that persist even at T=0. This is a novel noise mechanism, arising due to the excitation of collective angular modes on the Fermi surface, and does not resemble the well-known Johnson-Nyquist thermal noise. This novel noise disappears in the DC limit where the SNR is infinite. The frequency dependance of the output signal exhibits distinct peaks at odd multiples of the input frequency (f, 3 f, 5 f) , as shown in FIG. 9B.

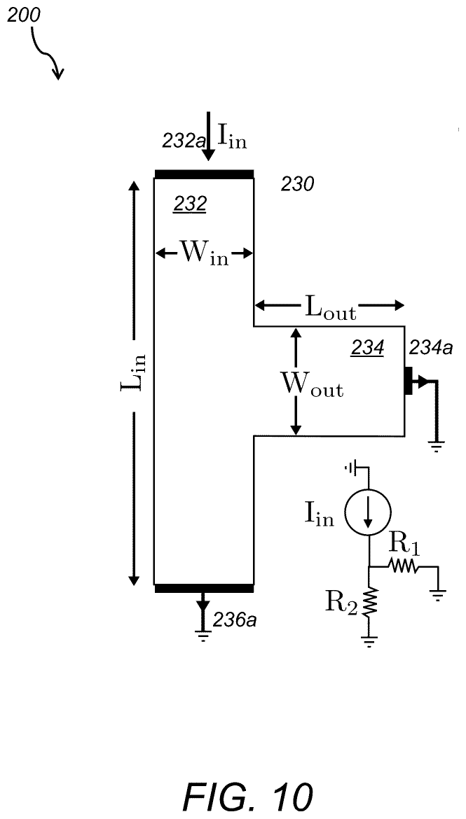

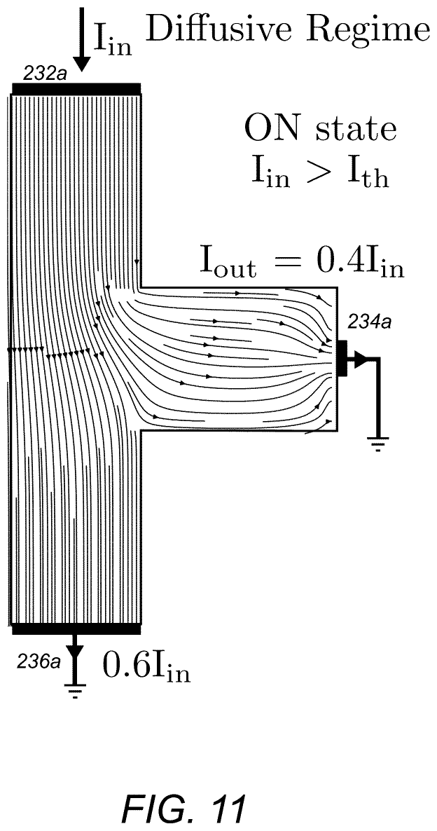

Referring to FIG. 10-FIG. 15, an electronic switch device 200 that can toggle between ON and OFF states, includes a two-dimensional electron gas (2DEG) layer 230, an input channel 232 of width Win ˜1 μm and length Lin ˜1 μm defined within the 2DEG that connects an input contact 232a to a grounded contact 236a, an output channel 234 (of possibly a different width Wm and length Lout) whose one end is connected perpendicularly to the input channel 232, and whose other end is connected to an output contact 234a. For simplicity, we take the two channels 232, 234 to be of equal widths: Wᵢₙ=Wₒᵤₜ=W=0.25 μm.

In FIG. 10, the input contact 232a, ground contact 236a and the output contact 234a are shown in the form of solid black bars which terminate the channels 232 and 234. The input contact 232a, ground contact 236a and the output contact 234a may span the full width of the channel or a part of the full width. In the present structure, the input and ground contacts span the full width of the input channel 232, and the output contact spans one-fifth the width of the output channel 234, and is placed at the center of the channel.

An ON state is defined as that in which a large amount of current flows from the input 232a to the output contact 234a, whereas an OFF state is defined by a much smaller value of current flowing between the input and output contact. Typical magnitude of ON and OFF states could be about 100 μA and about100 nA, respectively.

As described previously, electronic transport in the 2DEG can either be Ohmic/diffusive or non-Ohmic/non-diffusive. The former occurs when the mean free path due to momentum-relaxing scattering (e.g., carriers scattering against defects and phonons) is smaller than a certain critical length, which is approximately the device scale. For the structure being presently described, the typical device scale is the width of the channel W=0.25 μm . When the momentum-relaxing mean free path exceeds the critical length (i.e, transport is non-Ohmic/non-diffusive (either ballistic or hydrodynamic). Ballistic transport is characterized by carriers scattering predominantly against the device/channel boundaries whereas hydrodynamic transport is characterized by carriers scattering against each other, in a manner in which momentum is conserved amongst the carriers, in contrast to momentum-relaxing scattering due to defects and phonons.

Ballistic, hydrodynamic and Ohmic/diffusive transport regimes occur at distinct currents and temperatures. There exists a certain threshold current Iₜₕ˜100 μA below which transport is non-Ohmic/non-diffusive and above which it is Ohmic/diffusive. Below the threshold current, the regime is either ballistic or hydrodynamic depending on the magnitude of the current. For example, in GaAs/AlGaAs, the ballistic regime may occur for currents satisfying I≲100 nA and the hydrodynamic regime may occur for at higher currents (100 nA≲I≲100 μA).

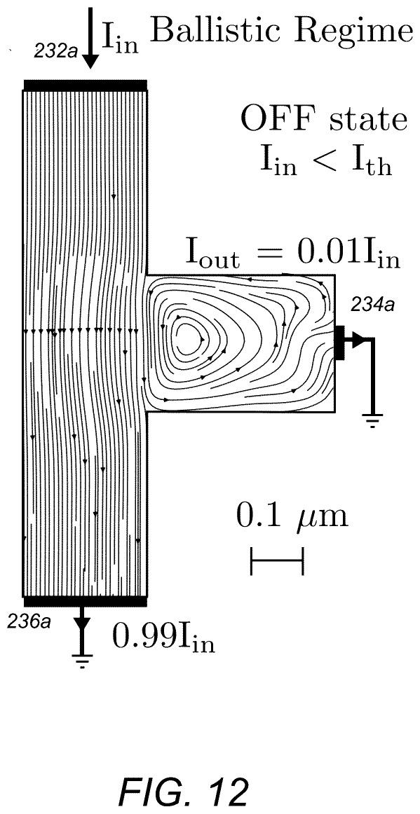

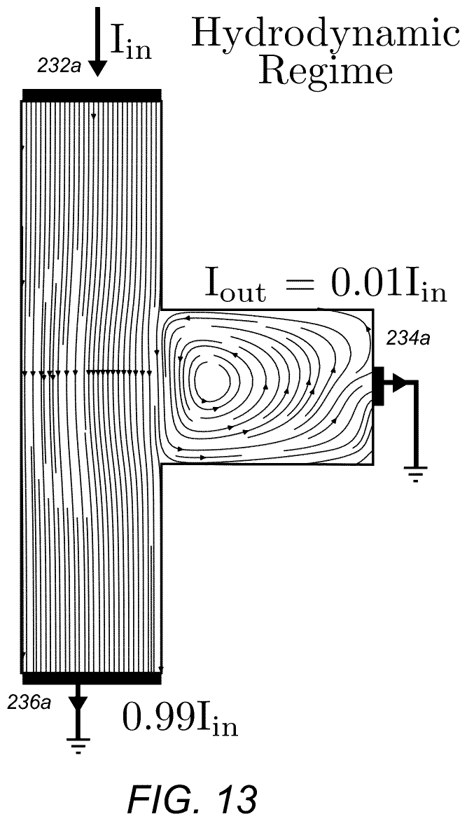

For input currents above the threshold current, I>Iₜₕ transport in the channels is Ohmic/diffusive, and the input current flows out through the output as well as to the grounded contact, as shown in FIG. 11. This is the ON state. For input currents below the threshold current, transport in the channels is non-Ohmic/non-diffusive, and a majority of the input current flows into the ground, as shown in FIG. 12 and FIG. 13. A current vortex forms in the output channel, which is perpendicular to the channel connecting the input and the ground contacts, and shuts off the current through the output contact. This is the OFF state.

In the ON state, the current in the output contact Iₒᵤₜ^{ON} can be a large fraction of the input current Iᵢₙ^{ON}. In one example, Iₒᵤₜ^{ON}=0.4 Iᵢₙ^{ON} . In the OFF state, current flowing through the output contact Iₒᵤₜ^{OFF} is a small fraction of the injected current Iᵢₙ^{OFF}. In one example, Iₒᵤₜ^{OFF}≃0.01 Iᵢₙ^{OFF}.

The OFF state is realized by either ballistic or hydrodynamic regime as shown in FIG. 12 and FIG. 13, respectively.

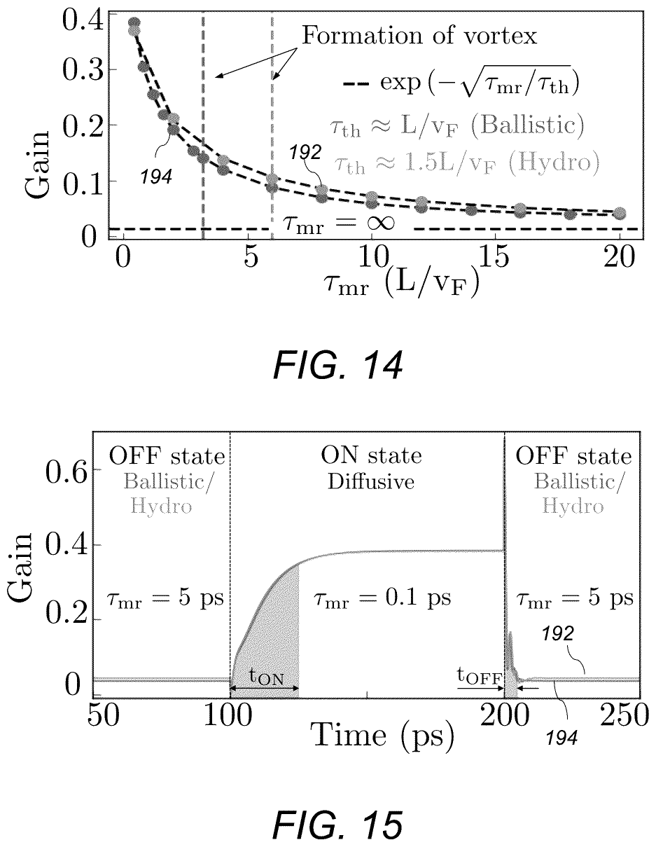

FIG. 14 shows the gain G, defined as G=Iₒᵤₜ/Iᵢₙ, as a function of momentum-relaxing time scale τₘᵣ, which is related to the momentum-relaxing mean free path lₘᵣ via τₘᵣ=lₘᵣ/v_{F}, where v_{F} is the Fermi velocity. The Fermi velocity can range between 0.1-1 μm/ps. The gain falls rapidly with decreasing τₘᵣ (or equivalently lₘᵣ), as transport in the 2DEG transitions from Ohmic/diffusive to a non-Ohmic/non-diffusive regime, thus enabling switching between ON and OFF states.

FIG. 15. shows the simulated time evolution of switching between ON and OFF states as τₘᵣ is varied between 5 ps (non-Ohmic/non-diffusive state) and 0.1 ps (Ohmic/diffusive state). In a physical device, a change in τₘᵣ is effected by changing the magnitude of the injected current, which results in heating and subsequent excitation of phonons. Beyond a threshold current, a sufficient number of phonons are excited which results in large momentum-relaxation and thus the onset of the Ohmic/diffusive regime.

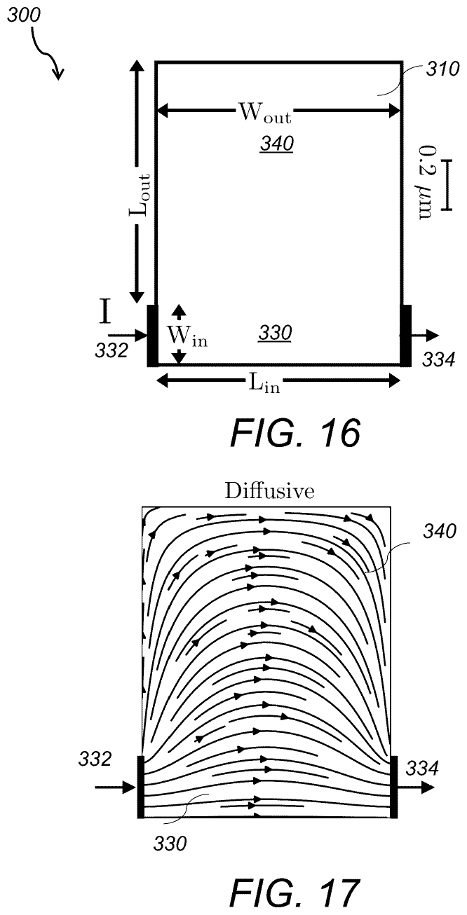

Referring to FIG. 16-FIG. 24, a device 300 used to generate magnetic fields over very small spatial scales a few microns), includes a two-dimensional electron gas 310 (2DEG), a channel 330 of width Win ˜1 μm and length Lin ˜1 μm defined within the 2DEG that connects two contacts, i.e., source 332 and drain 334, placed at opposite ends of the channel 330, another channel 340, called the output channel (of possibly a different width Wₒᵤₜ˜1 μm and length Lₒᵤₜ˜1 μm) whose one end is connected perpendicularly to the previous channel and extends away from the first channel with boundaries in the 2DEG formed using any of the methods described previously. In the structure being described, we take: Wᵢₙ=0.25 μm, Lᵢₙ=1 μm, Wₒᵤₜ=1 μm and Lₒᵤₜ=1 μm.

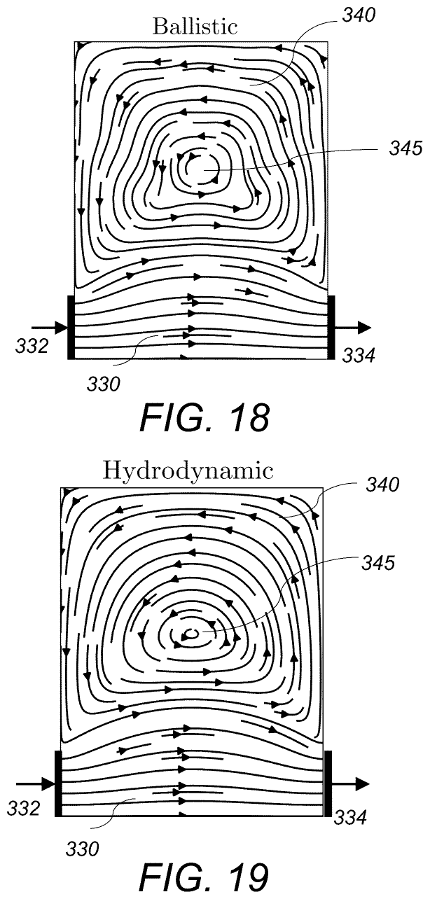

The 2DEG 310 needs to be in a non-Ohmic/non-diffusive transport regime, either ballistic or hydrodynamic. Ballistic and hydrodynamic regimes allow for the formation of sub-micron scale current vortices 345, i.e., the current j has a large curl (V×j), thus generating magnetic fields in the direction perpendicular to the 2DEG, as shown in FIG. 18 and FIG. 19. An Ohmic/diffusive regime is incapable of generating current vortices.

Given a 2DEG in a non-Ohmic/non-diffusive regime, when the source 332 and drain 334 are connected to a current source to inject and drain a current μA), a current vortex forms in the output channel 340, which is perpendicular to the source-drain channel 330. The current vortex 345 generates a magnetic field.

Referring to FIG. 19, in the hydrodynamic regime, there is a single vortex 345 in the system, independent of the length Lout of the output channel 340, which is perpendicular to the source-drain axis channel 330.

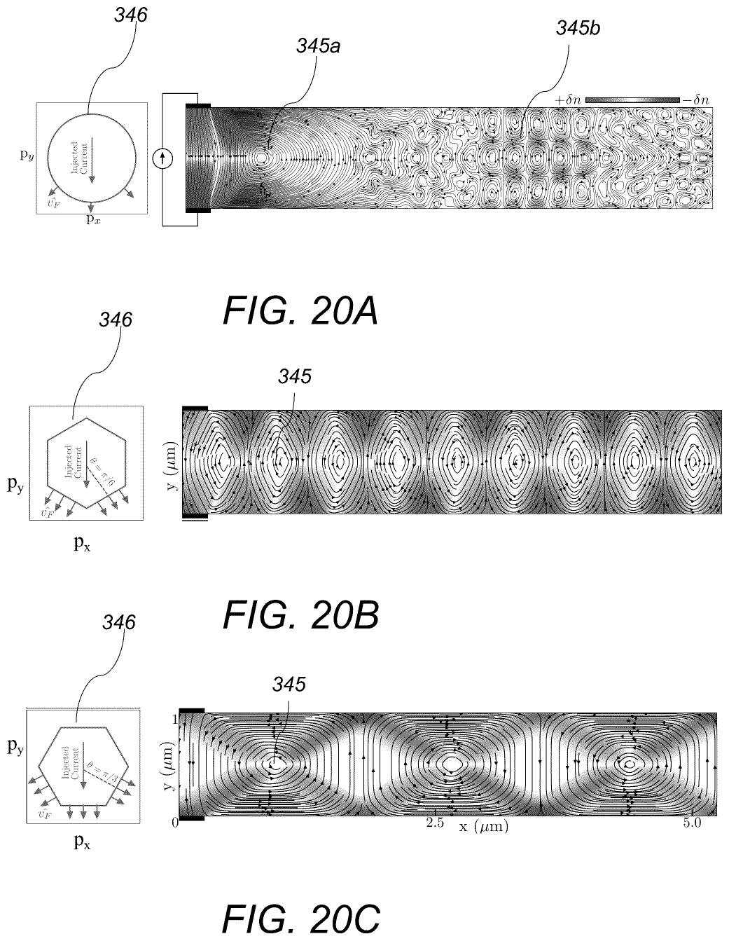

Referring to FIG. 20A-FIG. 20C, in the ballistic regime, different types of vortices can be generated, depending on the shape of the Fermi surface of the material being used. As shown in FIG. 20A, in materials with a circular Fermi surface (as in GaAs/AlGaAs, graphene), there is a single dominant current vortex 345a and several smaller vortices 345b that follow in the output channel. The magnetic fields generated for a circular Fermi surface are in a plane parallel to the 2DEG, and at an elevation of 250 nm. For materials wherein rotational symmetry of the Fermi surface is broken (i.e, the Fermi surface is a polygon and not a circle), repeated vortices 345 of the same shape and size can be formed, as shown in FIG. 20B and FIG. 20C. The magnetic fields generated for a hexagonal Fermi surface (as in PdCoO₂) are in a plane parallel to the 2DEG, at an elevation of 250 nm. FIG. 20B and FIG. 20C depict a hexagonal Fermi surface with two different orientations with respect to the injected current. In FIG. 20B the outgoing current exits the Fermi surface at an angle θ=π/6 relative to the injected current in two different directions. In FIG. 20C the outgoing current exits the Fermi surface at an angle θ=π/3 relative to the injected current in three different directions. The profiles in FIG. 20A-FIG. 20C are shown for devices with dimensions Wᵢₙ=0.25 μm, Lᵢₙ=1 μm, Wₒᵤₜ=1 μm and Lₒᵤₜ=1 μm.

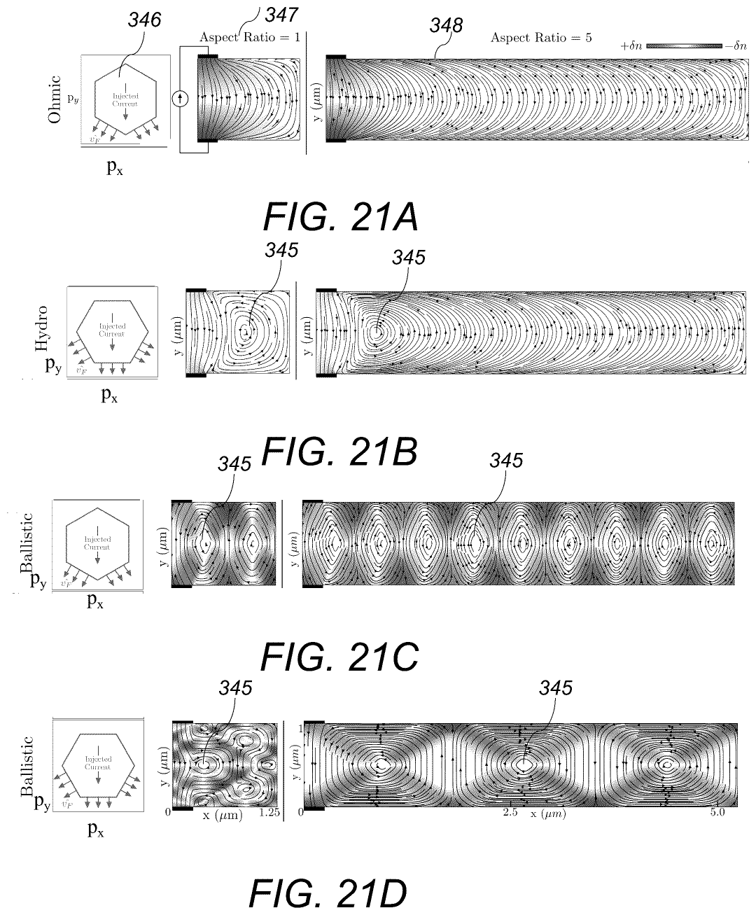

Referring to FIG. 21A-FIG. 21D, spatial profiles of the density and currents for devices with aspect ratio Lₒᵤₜ/Lᵢₙ=1 (left column 347) and Lₒᵤₜ/Lᵢₙ=5 (right column 348), and for various regimes are shown. The Fermi surface 346 and its relative orientation with respect to the injected current is shown in the left column. The Ohmic and hydrodynamic flow profiles do not depend on the shape and orientation of the Fermi surface, as shown in

FIG. 21A and FIG. 21B, respectively. The Ohmic regime does not allow for the formation of current vortices. Vortices 345 are formed in the hydrodynamic and ballistic regimes. The hydrodynamic regime only allows a single vortex to be formed, irrespective of the device size, whereas the ballistic regime allows for the formation of multiple vortices. For materials in which the Fermi surface the rotational symmetry is broken (i.e. the Fermi surface is a polygon, and not a circle), the shape and the number of vortices is determined by the orientation of the injected current with respect to the Fermi surface, as shown in FIG. 21C and FIG. 21D.

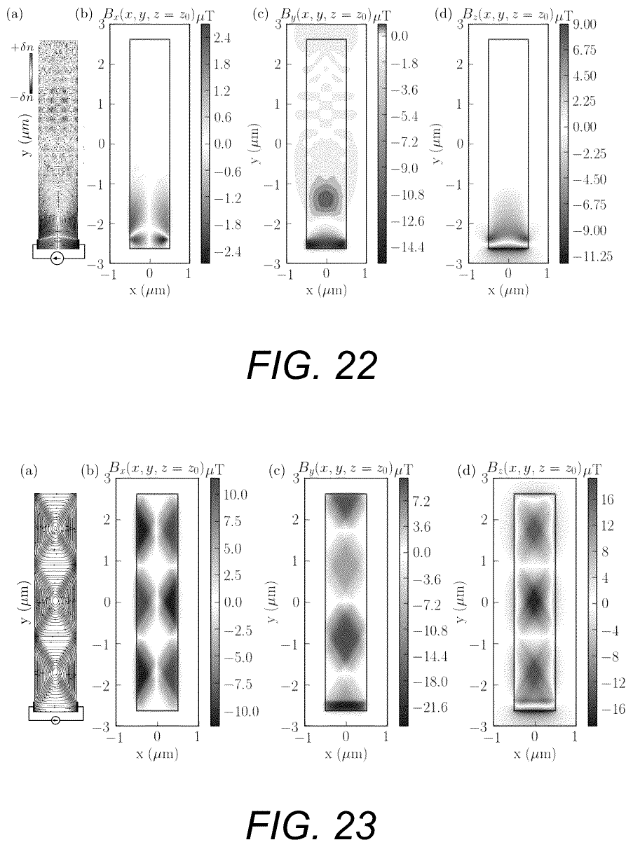

Referring to FIG. 22, the spatial profile of the density and current in a device made with a 2DEG having a circular Fermi surface, and with dimensions Wᵢₙ=0.25 μm, Lᵢₙ=1 μm, Wₒᵤₜ=1 μm and Lₒᵤₜ=5 μm are shown (graph a). Magnetic fields for the device shown in FIG. 22 graph (a), at a distance of 250 nm above the plane of the 2DEG are shown in the graphs (b)-(d). The current injected is 10 μA.

Referring to FIG. 23, the spatial profile of the density and current in a device made with a 2DEG having a hexagonal Fermi surface, and with dimensions Wᵢₙ=0.25 μm, Lᵢₙ=1 μm, Wₒᵤₜ=1 μm and Lₒᵤₜ=5 μm are shown (graph a). Magnetic fields for the device shown in FIG. 23(a), at a distance of 250 nm above the plane of the 2DEG are shown in the graphs (b)-(d). The current injected is 10 μA. In FIG. 23 the outgoing current exits the

Fermi surface at an angle θ=π/3 relative to the injected current in three different directions.

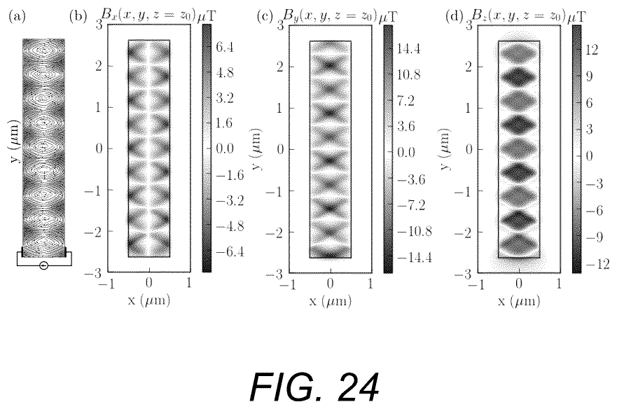

Referring to FIG. 24, the spatial profile of the density and current in a device made with a 2DEG having a hexagonal Fermi surface, and with dimensions Wᵢₙ=0.25 μm, Lᵢₙ=1 Wₒᵤₜ=1 μm and Lₒᵤₜ=5 μm (graph a). Magnetic fields for the device shown in

FIG. 24 graph (a), at a distance of 250 nm above the plane of the 2DEG are shown in the graphs (b)-(d). The current injected is 10 μA. In FIG. 24 the outgoing current exits the Fermi surface at an angle θ=π/6 relative to the injected current in two different directions.

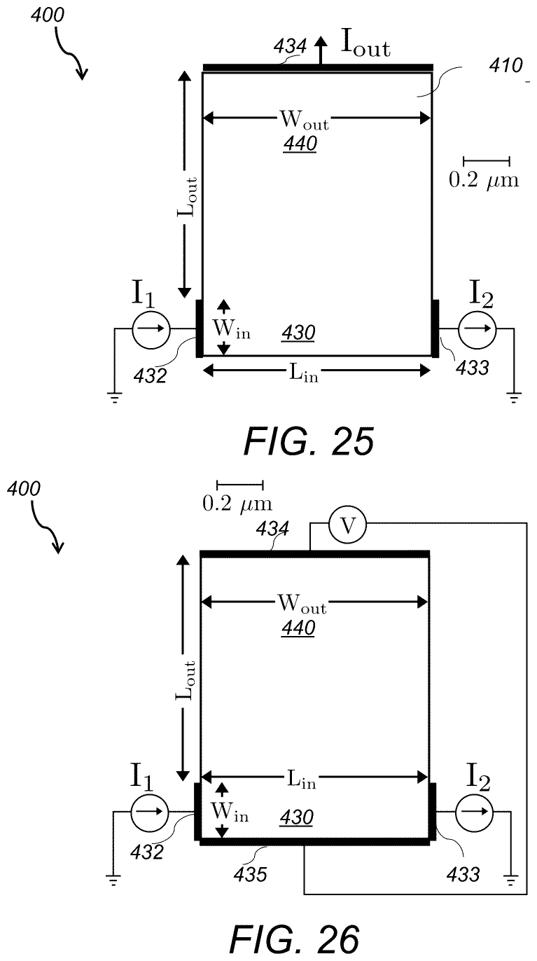

Referring to FIG. 25-FIG. 32, a device 400 used as a frequency mixer, rectifier, or multiplier, includes a two-dimensional electron gas 410 (2DEG), a first input contact 432, a second input contact 433 and an output contact 434. The 2DEG operates in the non-Ohmic/non-diffusive regime (either ballistic or hydrodynamic regime). A first channel 430 is defined within the 2DEG in the area that connects the two input contacts 432, 433 (INPUT1 and INPUT2) which are placed at opposite ends of the channel. In one example, channel 430 has a width Win ˜1 μm and length Lᵢₙ˜1 μm. A second channel 440 is defined in the area of the 2DEG between the output contact 434 and the first channel 430. One end of channel 440 is connected perpendicularly to channel 430, and an opposite end is connected to the output contact 434. Channel 440 has possibly a different width Wₒᵤₜ and length Lₒᵤₜ than the width and length of the first channel 430. Device 400 can output a current Iₒᵤₜ or a voltage, V as shown in FIG. 25 and FIG. 26, respectively. In the voltage output mode, there is an additional contact 435 placed at the bottom edge of the input channel 430, and the voltage difference is measured between contacts 434 and 435 as shown in FIG. 26. In this example, we have: Wᵢₙ=0.25 μm, Lᵢₙ=1 Wₒᵤₜ=1 μm and Lₒᵤₜ=1 μm. Contacts 432, 433, and 434, 435 span the full width of the channels 430 and 440, respectively. In other embodiments, contacts 432, 433, and 434, 435 span part of the width of the channels 430 and 440, respectively.

Device 400 is fed with inputs using a current source I₁ connected to one of the inputs 432 (i.e., INPUT1) and another current source I₂ connected to the other input 433 (i.e., INPUT2). Both current sources I₁ and I₂ are connected to a common external ground. The output contact 434 may be connected to an external circuit that makes use of the device output. The output of the device can be a current Iₒᵤₜ or a voltage V with no flow of current. To measure the current output, the output terminal 434 of the device may be connected to an ammeter, and to measure a voltage output, the output terminal may be connected to a voltmeter, as shown in FIG. 26.

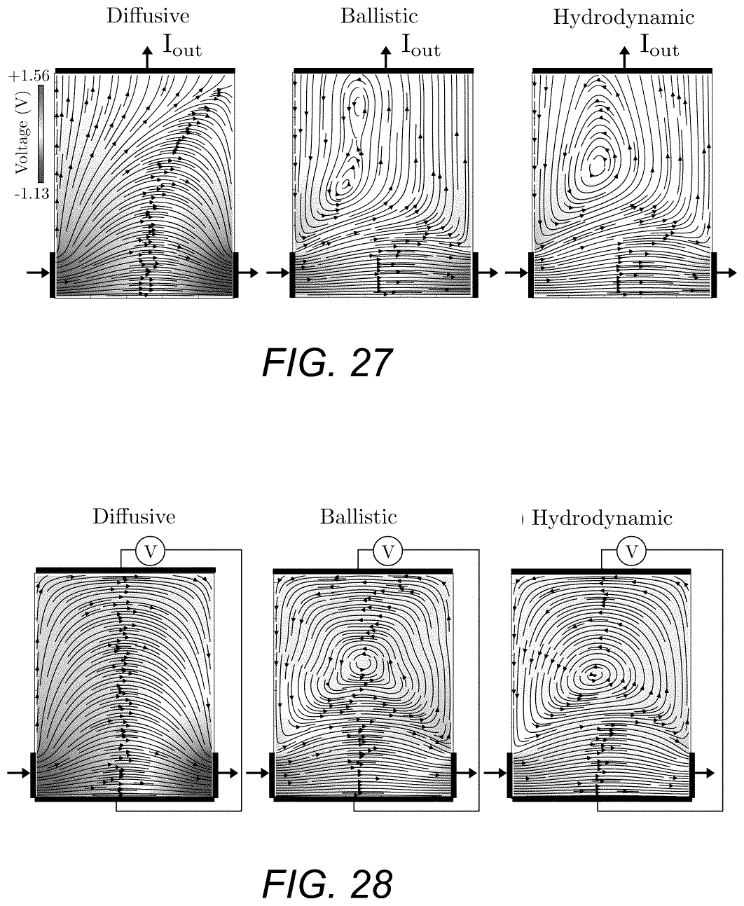

Spatial profiles of the voltages and currents in the Ohmic/diffusive, ballistic and hydrodynamic regimes for the current mode and voltage mode are shown in FIGS. 27 and FIG. 28, respectively. The injected current Ii is ≃26 μA, and the background density in the 2DEG is 10¹² [symbol] ⁻², with a Fermi velocity ν_{F}=1 μm/ps. The output current or voltage in the Ohmic/diffusive regime is much smaller than that in the ballistic and hydrodynamic regimes.

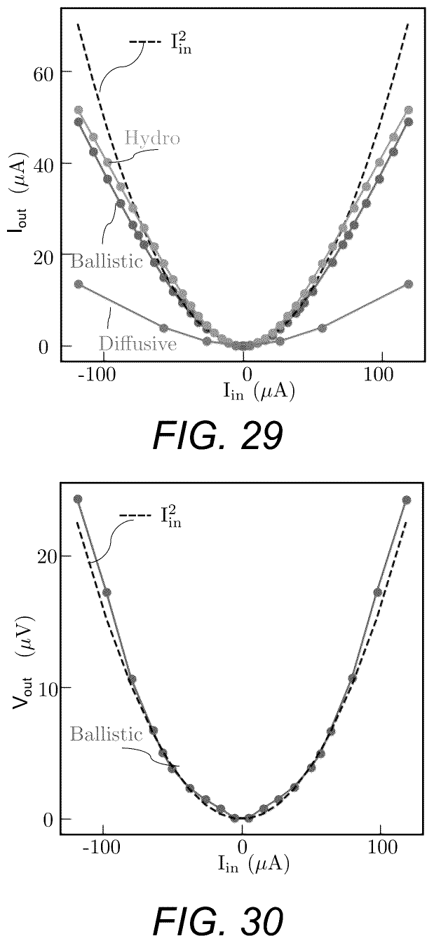

One particular application of device 400 is as a DC frequency multiplier, as shown in FIG. 29 and FIG. 30. When two DC currents I₁ and I₂ of equal magnitude Iᵢₙ are injected at the two inputs 432, 433, the output current lout is a nonlinear function of the input current Iᵢₙ, and in this case Iₒᵤₜ is proportional to the square of the input current Iᵢₙ², as shown in FIG. 29. An appreciable output is only obtained in a non-Ohmic/non-diffusive regime (ballistic or hydrodynamic), with the output in the Ohmic/diffusive regime being much smaller.

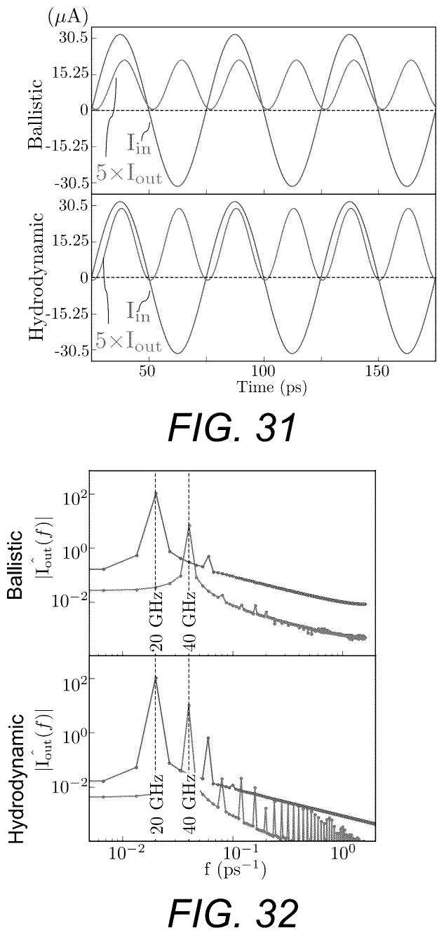

In another application device 400 is used as an AC frequency multiplier, as shown in FIG. 31 and FIG. 32. In this application device 400 has the following dimensions: Wᵢₙ=0.25 μm, Lᵢₙ=1 μm, Wₒᵤₜ=1 μm and Lₒᵤₜ=1 μm, and operates in the current mode. The background density in the 2DEG is 10¹² cm [symbol] ⁻² with a Fermi velocity ν_{F}=1 μm/ps. Two AC current inputs I₁, =I₂=I are set to be equal with equal frequency (f) of 20 GHz, and are injected at the two inputs 432, 433. The output current Iₒᵤₜ contains a DC component and an AC component with frequency that is double the frequency of the input current, i.e., 2 f . The device therefore functions as a rectifier and a frequency multiplier.

When two AC current inputs of unequal frequencies (i.e., f₁ and f₂) are injected at the two inputs 432, 433, the current at the output lout contains frequencies f₁+f₂ and |f₁−f₂|. In this case the device 400 is used as a frequency mixer.

In another specific configuration, the device 400 is used as a frequency mixer, as follows: Given an input signal Iᵢₙ with frequency f connected to contact 432 (INPUT1), a local oscillator (an AC current source) with a known frequency f_{LO} is connected to contact 433 (INPUT2). The current Iₒᵤₜ at the output contact 434 will then contain the frequencies f+f_{LO} and |f−f_{LO}|.

The device operates at high-frequencies, up to several THz. The high frequency of operation is enabled by the completely planar flow of current, i.e., the flow of current is confined to within the 2DEG.

The device can also be used to perform a variety of nonlinear operations such as multiplication and phase detection of AC signals. The nonlinearity in the device arises due to the Fermi-Dirac statistics obeyed by the charge carriers injected through the input contacts. This nonlinearity has no threshold and the device can therefore function with an arbitrarily small magnitude of input currents.

The device can also be used to rectify radiation incident on an antenna by connecting the two inputs (INPUT1, INPUT2) to the terminals of an antenna.

Referring to FIG. 33-FIG. 37, an electronic phase shifter device 500 is capable of inducing a desired phase-shift to an input AC signal. Device 500 includes an input channel 530 in a 2DEG 510 with length Lin and width Win. A contact 532 through which the input current Iᵢₙ is fed is placed at the left edge of this channel 530. The input channel 530 is connected to a “middle” channel 550 with length L_{mid} and width W_{mid} that is placed perpendicular to the input channel 530. The middle channel 550 then connects to a mixing channel 560 of length Lₘᵢₓ and width Wₘᵢₓ, with the same orientation as the middle channel 550. A grounded contact 536 is placed at the left edge of the mixing channel 560. The mixing channel 560 connects to an output channel 540 at the top edge through an opening 570 of width Wₒₚₑₙ. The remaining part of the edge of the mixing channel that is shared with the output channel is a channel boundary that is fabricated using the same methods used to define boundaries in the 2DEG. The output channel 540 at the top, with length Lout and width Wₒᵤₜ, completes the device. The orientation of the output channel 540 is the same as the input channel 530, and is perpendicular to the mixing channel 560. A grounded contact 535 is placed at the left edge of the output channel 540, and an output contact 534 through which an output current Iₒᵤₜ is generated is placed at the right edge.

The input AC current has the form Iᵢₙ =Aᵢₙsin(ωt) and Iₒᵤₜ=Aₒᵤₜsin(ωt+ϕ) where Aᵢₙ and Aₒᵤₜ are the amplitudes of the input and output currents (˜1-100 μA), ω is the frequency (˜1-100 GHz) and ϕ is the phase difference.

In one example, device 500 has the following dimensions : Lᵢₙ=0.5 μm, Wᵢₙ=0.25 μm, L_{mid}=0.5 μm, W_{mid}=0.5 μm, Lₘᵢₓ=0.25 μm, Wₘᵢₓ=0.5 μm, Wₒₚₑₙ=0.25 μm, Lₒᵤₜ=0.5 μm, Wₒᵤₜ=0.75 μm. In other embodiments, Lᵢₙ=W_{mid}=Wₘᵢₓ=Lₒᵤₜ=W, and show the device characteristics for varying W.

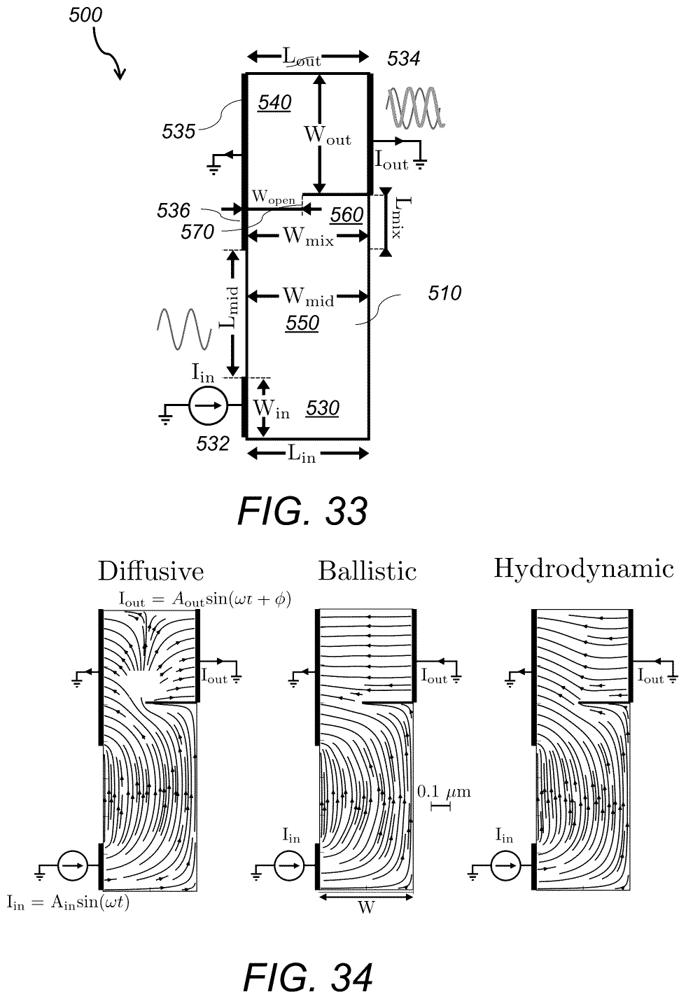

Referring to FIG. 34, in an Ohmic/diffusive flow, and for a DC input, the current in the output channel is in the same direction as the input. Further, the output has a much smaller magnitude compared to the input current because the current in the output channel is split between the grounded contact at the left edge of the output channel and the output contact. When transport in the device is non-Ohmic/non-diffusive (i.e., either ballistic or hydrodynamic), the DC flow in the output channel is perpendicular to the direction of the input current, and with a gain (defined by Aₒᵤₜ/Aᵢₙ, where Aₒᵤₜ and Aᵢₙ are the amplitudes of the time-varying currents) greater than unity that can be controlled by the output channel width Wₒᵤₜ.

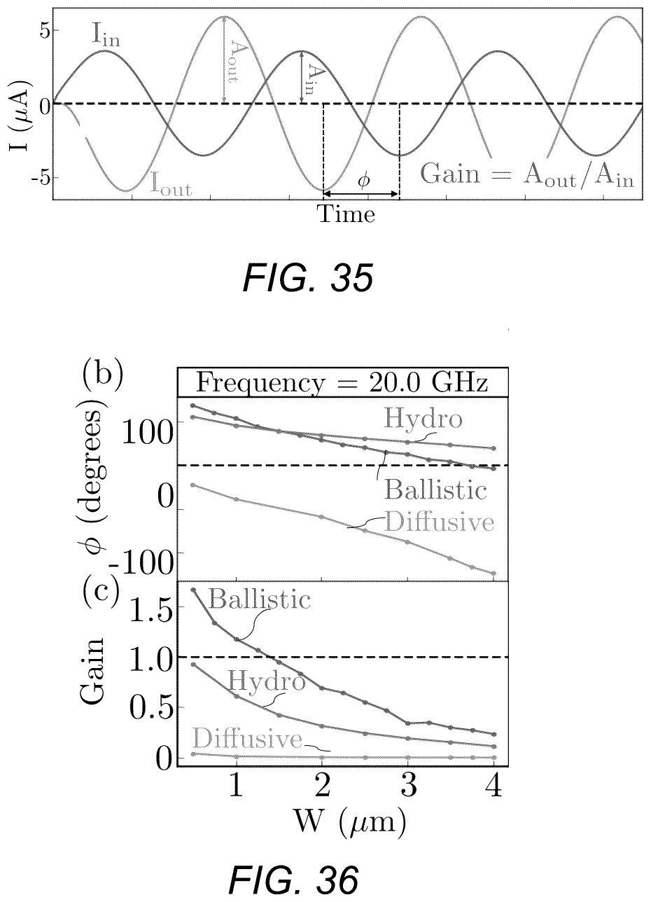

For an AC input current, the output has a phase shift ϕ with respect to the input current, as illustrated in FIG. 35. When the device is operating in a non-Ohmic/non-diffusive regime, the obtained phase shift ϕ is large (≃100 degrees). In an Ohmic/diffusive regime, the phase shift ϕ is much smaller, and is set by the path length between the input and output contact.

Along with a large phase shift, the output AC current can have a gain greater than unity when the device is operating in a non-Ohmic/non-diffusive regime. In an Ohmic/diffusive regime, the gain is always less than unity, i.e., the device is lossy, as shown in FIG. 36 graph (c).

The obtained phase shift can be controlled by modifying the dimensions of the device. As an example, we consider an embodiment where W is varied, with W being defined as W=Lᵢₙ=W_{mid}=Wₘᵢₓ=Lₒᵤₜ. FIG. 36 shows the obtained phase shift at 20 GHz as W is varied from 0.5-4 μm, with all other dimensions being equal to the embodiment shown in FIG. 33. The associated gain is shown in FIG. 36. The gain may be controlled by changing the output channel width Wₒᵤₜ. The phase shift may also be controlled by changing other parameters such as L_{mid}, Wₒₚₑₙ, and Lₘᵢₓ.

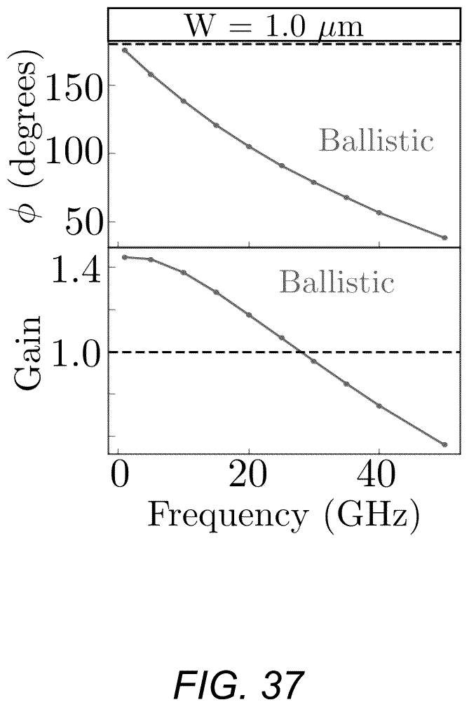

FIG. 37 shows the variation of the phase shift ϕ as a function of the frequency, up to 50 GHz, for the embodiment shown in FIG. 33 with W=1 μm. FIG. 37 also shows the associated gain as a function of frequency. The output of the disclosed phase shifter device may be connected to the input contact/channel of the passive amplifier disclosed in FIG. 3A to obtain a large gain.

Other embodiments of the above mentioned devices 100, 200, 300, 400 and 500 include one or more of the following. The device boundaries are defined by the material boundaries, similar to the amplifier structure in FIG. 3D. The device boundaries are formed lithographically within the 2DEG structure, similar to the amplifier embodiments in FIG. 3B and FIG. 3C. The inputs and outputs are metal contacts, similar to the amplifier embodiments in FIG. 3B and FIG. 3D. The inputs and outputs are channels formed within the 2DEG structure, similar to the amplifier embodiment in FIG. 3C. The inputs and outputs are a combination of metal contacts and channels. The devices may have a linear output or a non-linear output. Other device embodiments include sensors, magnetic field sensors and bolometers, among others. Several embodiments of the present invention have been described. Nevertheless, it will be understood that various modifications may be made without departing from the spirit and scope of the invention. Accordingly, other embodiments are within the scope of the following claims.

What is claimed is:

1. An electronic device comprising:
a two-dimensional electron system (2DES) having a two-dimensional electron gas (2DEG) area and wherein charge particle transport is confined within the 2DEG area;
a plurality of contacts arranged around the 2DEG area ;and
wherein the charge particle transport within the 2DEG area operates within ballistic or hydrodynamic transport regimes.

2. The device of claim 1, wherein charge particle transport within the 2DEG area has a momentum-relaxing mean free path equal or larger than the 2DEG area's scale W:
lₘᵣ≳W.

3. The device of claim 1 wherein the 2DEG comprises graphene.

4. The device of claim 1, wherein the 2DEG layer is arranged between two layers of semiconductor materials.

5. The device of claim 1, wherein the 2DEG layer is arranged between an AlGaAs layer and a GaAs layer.

6. The device of claim 1, wherein the 2DEG layer is arranged between a first layer of hBN layer and a second layer of hBN.

25 7. The device of claim 1, wherein the 2DES comprises one of amplifiers, electronic vortex switches, frequency mixers, rectifiers, multipliers, electrically-controlled micro-scale magnetic field generators, sensors, magnetic sensors, bolometers, or phase shifters.

8. The device of claim 1, comprising a non-linear output.

9. The device of claim 1, wherein the charge particle transport is one-dimensional.

10. The device of claim 1, wherein the charge particle transport is two-dimensional.

11. An amplifier device comprising:
a two-dimensional electron system (2DES) having a two-dimensional electron gas (2DEG) area arranged between a first semiconductor layer and a second semiconductor layer, and wherein a primary channel is formed within the 2DEG area and wherein charge particle transport is confined within the primary channel;
a plurality of contacts arranged around the primary channel, wherein the contacts comprise an input/emitter contact, an output/collector contact and a ground/base contact; and
wherein the charge particle transport within the primary channel operates within ballistic or hydrodynamic transport regimes.

12. The amplifier device of claim 11, wherein charge particle transport within the primary channel has a momentum-relaxing mean free path (lₘᵣ) equal or larger than the primary channel's width W:
lₘᵣ≳W.

13. The amplifier device of claim 11, wherein the primary channel is formed within the 2DEG by lithographic techniques comprising etching at a top layer, electrostatic gating, dry/wet etching, reactive ion etching, focused ion beam milling, electron beam lithography, and photo-lithography.

14. The amplifier device of claim 11, wherein the contacts comprise one of metal contacts or secondary channels formed within the primary channel.

15. The amplifier device of claim 11, wherein an input current signal injected into the input/emitter contact is amplified by an amount G=W/Wₑ at the output/collector contact, wherein W is the primary channel's width and Wₑ is the input/emitter contact's width.

16. An electronic switch device comprising:
a two-dimensional electron system (2DES) having a two-dimensional electron gas (2DEG) area, and wherein an input channel is formed within the 2DEG area along a first direction and an output channel is formed within the 2DEG area along a second direction and has a first end connected perpendicularly to the input channel, and wherein charge particle transport is confined within the input and output channels;
an input contact arranged at a first end of the input channel, a ground contact arranged at a second end of the input channel opposite to the first end and an output contact arranged at a second end opposite to the first end of the output channel; and
wherein the charge particle transport within the input and output channels operates within ballistic or hydrodynamic transport regimes in a switch OFF state and within Ohmic/diffusive transport regime in a switch ON state.

17. The electronic switch device of claim 16, wherein a first amount of current flows from the input contact to the output contact in the ON state and a second amount of current flows from the input contact to the output contact in the OFF state and wherein the second amount of current is smaller than the first amount of current.

18. A device used to generate a magnetic field comprising:
a two-dimensional electron system (2DES) having a two-dimensional electron gas (2DEG) area, and wherein an input channel is formed within the 2DEG area along a first direction and an output channel is formed within the 2DEG area along a second direction and has a first end connected perpendicularly to the input channel and extending away from the input channel, and wherein charge particle transport is confined within the input and output channels;
an input contact arranged at a first end of the input channel, an output contact arranged at a second end of the input channel opposite to the first end; and
wherein a current vortex is formed within the output channel when the charge particle transport within the input channel operates within ballistic or hydrodynamic transport regimes and wherein the current vortex generates a magnetic field in a direction perpendicular to the 2DEG area and in a plane parallel to the 2DEG area.

19. The device of claim 18, wherein when the charge particle transport within the input channel operates within the hydrodynamic transport regime a single current vortex is formed within the output channel.

20. The device of claim 18, wherein when the charge particle transport within the input channel operates within the ballistic transport regime a plurality of current vortices is formed within the output channel.

21. The device of claim 20, wherein the current vortices configuration depends upon the 2DEG material's Fermi surface shape.

22. The device of claim 20, wherein for a 2DEG material with a circular Fermi surface the current vortices comprise a first dominant current vortex and several smaller current vortices.

23. The device of claim 20, wherein for a 2DEG material with a non-circular Fermi surface the current vortices comprise several current vortices of the same size and shape.

24. An electronic device comprising:
a two-dimensional electron system (2DES) having a two-dimensional electron gas (2DEG) area, and wherein a first channel is formed within the 2DEG area along a first direction and a second channel is formed within the 2DEG area along a second direction and has a first end connected perpendicularly to the first channel, and wherein charge particle transport is confined within the first and second channels;
a first input contact arranged at a first end of the first channel, a second input contact arranged at a second end of the first channel opposite to the first end and a first output contact arranged at a second end opposite to the first end of the second channel;
wherein a first current input and a second current input are injected into the first channel via the first input contact and the second input contact, respectively, and an output current exits the second channel through the first output contact; and
wherein the charge particle transport within the first and second channels operates within ballistic or hydrodynamic transport regimes and the output current is a non-linear function of the first and second current inputs.

25. The device of claim 24, wherein the first and second input currents are DC currents and the device is used as a DC frequency multiplier.

26. The device of claim 24, wherein the first and second input currents are AC currents having a first and second frequencies, respectively, and the output current comprises a DC component and an AC component, and wherein when the first and second frequencies are the same the AC component has a frequency double the first or the second frequency and the device is used as a rectifier and an AC frequency multiplier.

27. The device of claim 24, wherein the first and second input currents are AC currents having a first and second frequencies, respectively, and the output current comprises a DC component and an AC component, and wherein when the first and second frequencies are not the same the AC component comprises frequencies equal to the sum of the first and second input currents' frequencies and the difference of the first and second input currents' frequencies and the device is used as a frequency mixer.

28. The device of claim 24, further comprising a voltage difference across the first output contact and a contact arranged at a bottom edge of the input channel opposite to the first output contact.

29. An electronic phase shifter device comprising:
a two-dimensional electron system (2DES) having a two-dimensional electron gas (2DEG) area, and wherein an input channel is formed within the 2DEG area along a first direction, and a middle channel is formed within the 2DEG area along a second direction and has a first end connected perpendicularly to the input channel, and a mixing channel is formed within the 2DEG area along the second direction having an end connecting to a second end of the middle channel, opposite the first end, and wherein charge particle transport is confined within the input channel, the middle channel and the mixing channel;
an input contact arranged at a first side edge of the input channel, a first grounded contact arranged at a first side edge of the middle channel, a second grounded contact arranged at a first side edge of the output channel, and an output contact arranged at a second side edge of the output channel;
wherein when the charge particle transport within the input, middle and output channels operates within ballistic or hydrodynamic transport regimes a current flow in the output channel is phase shifted relative to a current flow in the input channel.

30. The device of claim 29, wherein for a DC input current, the current flow in the output channel is perpendicular to the current flow in the input channel.
